(19) United States
(12) Patent Application Publication
(10) Pub. No.: US 2026/0315838 A1
(43) Pub. Date: Oct. 15, 2026

(54) Composite Connector Comprising Deformable Section with Interruptible Signal-Transmissive Pathway

(71) Applicant: 3M INNOVATIVE PROPERTIES COMPANY, St. Paul, MN (US)

(72) Inventors: Michael T. Weiss, Hastings, MN (US); Daniel B. Taylor, White Bear Lake, MN (US); Jonathan J. Lepp, Eagan, MN (US); Ronald D. Jesme, Plymouth, MN (US)

(21) Appl. No.: 18/880,949

(22) PCT Filed: Jul. 11, 2023
(86) PCT No.: PCT/IB2023/057111

§ 371 Date: Jan. 3, 2025

Related U.S. Application Data
(60) Provisional application No. 63/390,918, filed on Jul. 20, 2022.

(51) Int. Cl. A62B 35/00; A62B 35/04; G01D 5/22; G01D 5/32; H05K 1/02; H05K 1/09; H05K 1/16

(52) U.S. Cl. CPC A62B 35/0075; A62B 35/0037; A62B 35/0093; G01D 5/2216; G01D 5/32; H05K 1/0218; H05K 1/0277; H05K 1/092; H05K 1/165; A62B 35/005; A62B 35/04

(57) ABSTRACT

A composite connector for use with a fall-protection apparatus, the composite connector including a frame and a shroud that is mounted on the frame. The shroud includes a deformable section that at least partially defines a connection area for connecting the composite connector to a support item. The composite connector includes a fall-detection module that includes an interruptible signal-transmissive pathway that passes through at least a portion of the deformable section of the shroud.

### BACKGROUND

Fall-protection apparatus, systems, and methods of using such apparatus and systems, have found wide use in applications such as building construction, aerial lifts and the like.

### SUMMARY

In broad summary, herein is disclosed a composite connector for use with a fall-protection apparatus. The composite connector comprises a frame and a shroud that is mounted on the frame. The shroud comprises a deformable section that at least partially defines a connection area for connecting the composite connector to a support item. The composite connector comprises a fall-detection module that includes an interruptible signal-transmissive pathway that passes through at least a portion of the deformable section of the shroud. Apparatus, systems and methods that use such a composite connector are also disclosed. These and other aspects will be apparent from the detailed description below. In no event, however, should this broad summary be construed to limit the claimable subject matter, whether such subject matter is presented in claims in the application as initially filed or in claims that are amended or otherwise presented in prosecution.

### BRIEF DESCRIPTION OF THE DRAWINGS

FIG. 1 is a side perspective view of an exemplary fall-protection apparatus.

FIG. 2 is a rear view of an exemplary fall-protection harness as worn by a human user.

FIG. 3 is a side view of an exemplary composite connector suitable for use with a fall-protection apparatus and harness.

FIG. 4 is a side view of an exemplary frame of a composite connector.

FIG. 5 is a side view of an exemplary shroud of a composite connector.

FIG. 6 is a side perspective view of an exemplary shroud of a composite connector.

FIG. 7 is a side perspective partially exploded view of an exemplary shroud of a composite connector.

FIG. 8 is a side cross-sectional view of an exemplary composite connector.

FIG. 9 is a magnified view of an exemplary deformable section of an exemplary shroud piece of a shroud.

FIG. 10 is a cross-sectional view of an exemplary deformable section of an exemplary shroud, taken along line 10-10 of FIG. 9.

FIG. 11 is a side perspective partially exploded view of an exemplary shroud and an exemplary fall-detection module comprising an exemplary signal-transmissive pathway.

FIG. 12 is an isolated view of an exemplary signal-transmissive pathway in the form of an electrically-conductive trace disposed on a flex circuit.

Like reference numbers in the various figures indicate like elements. Some elements may be present in identical or equivalent multiples; in such cases only one or more representative elements may be designated by a reference number but it will be understood that such reference numbers apply to all such identical elements. Unless otherwise indicated, all figures and drawings in this document are not to scale and are chosen for the purpose of illustrating different embodiments of the invention. In particular the dimensions of the various components are depicted in illustrative terms only, and no relationship between the dimensions of the various components should be inferred from the drawings, unless so indicated. Although terms such as “top”, bottom“, ”upper“, lower”, “under”, “over”, “front”, “back”, “up” “down”, and “first” and “second” may be used in this disclosure, it should be understood that those terms are used in their relative sense only unless otherwise noted.

As used herein as a modifier to a property or attribute, the term “generally”, unless otherwise specifically defined, means that the property or attribute would be readily recognizable by a person of ordinary skill but without requiring a high degree of approximation (e.g., within +/−20 % for quantifiable properties). The term “substantially”, unless otherwise specifically defined, means to a high degree of approximation (e.g., within +/−10% for quantifiable properties). The term “essentially” means to a very high degree of approximation; it will be understood that the phrase “at least essentially” subsumes the specific case of an “exact” match. However, even an “exact” match, or any other characterization using terms such as e.g. same, equal, identical, uniform, constant, and the like, will be understood to be within the usual tolerances or measuring error applicable to the particular circumstance rather than requiring absolute precision or a perfect match. The term “configured to” and like terms is at least as restrictive as the term “adapted to”, and requires actual design intention to perform the specified function rather than mere capability of performing such a function. Terms such as “a” and “an”, particularly when used in combination with “comprises”, “comprising”, and like terms, will be understood to mean “at least one”; e.g., the phrase “comprises a signal-transmissive pathway” means “comprises at least one signal-transmissive pathway”.

### DETAILED DESCRIPTION

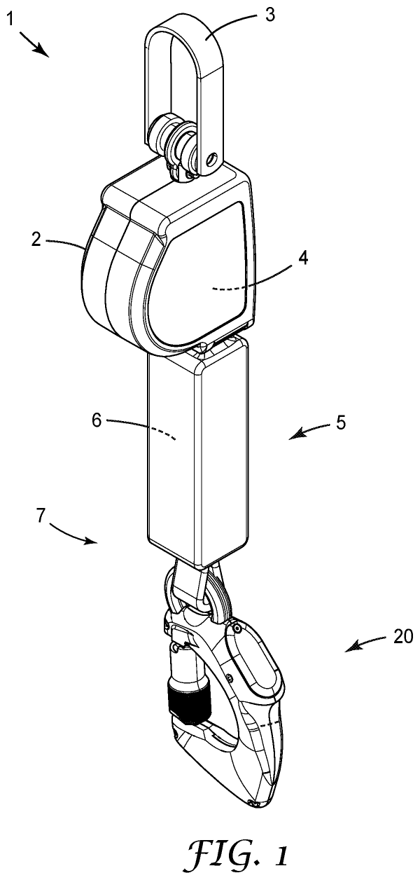

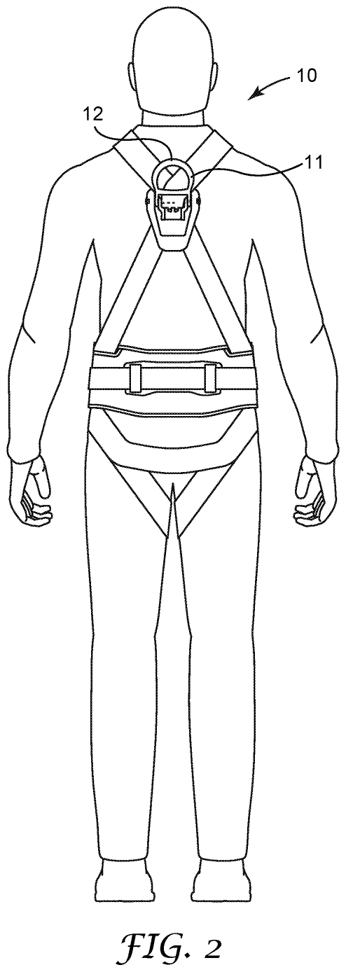

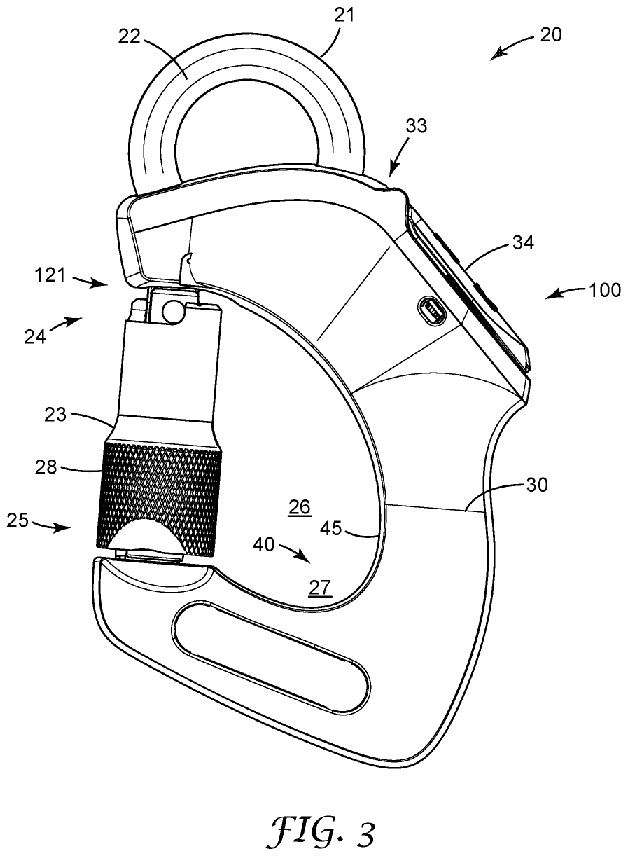

As depicted in exemplary embodiment in FIGS. 1 and 3, disclosed herein is a composite connector 20. Composite connector 20 is configured to be used with a fall-protection apparatus 1 as shown in exemplary embodiment in FIG. 1. Apparatus 1 and composite connector 20 are configured to be used with a fall-protection harness 10 of the general type shown in exemplary embodiment in FIG. 2, that is wearable by a human user. Fall-protection apparatus 1 and fall-protection harness 10 collectively form a fall-protection safety system.

A fall-protection harness 10, often referred to as a full-body safety harness, is used in various circumstances and workplaces in which persons are at elevated height or are otherwise at risk of falling. Fall-protection full-body safety harnesses are required to meet various standards (as promulgated e.g. by ANSI), are required by OSHA for certain types of work activities, and will be distinguished from other types of harnesses such as e.g. SCBA harnesses, climbing harnesses, and general-use harnesses such as for backpacks, hiking, and the like. As illustrated in generic representation in FIG. 2, a full-body fall-protection safety harness 10 will comprise first and second shoulder straps that extend over the top of the shoulders. Other straps are also present, e.g. chest straps that extend down the user's frontal torso, and leg straps that encircle the upper thighs. In some embodiments a harness may comprise a waist strap that encircles the waist/hip area of the user. Such straps are interconnected with each other to form the harness and are often fitted with various pads to enhance the comfort of the harness, as well as various buckles, latches, connectors, loops, strap guides, and so on. In many safety harness designs, the first and second shoulder straps meet, overlap and cross each other at a dorsal crossing area, with a dorsal D-ring 11 being non-removably attached to the harness at the dorsal crossing areas in the general manner shown in FIG. 2, e.g. to allow a safety line of a fall-protection safety apparatus to be attached to the harness. Other D-rings may also be present, for similar purposes.

Fall-protection apparatus 1 comprises at least one safety line 5, with the term safety line denoting a line that is configured to bear the weight of a human user and is further configured to withstand any momentarily higher force resulting e.g. from the arresting of a fall of the human user. The term line broadly encompasses any cable, strap, webbing, rope, lanyard, or the like. In various embodiments such a safety line may be e.g. round or flat in cross-section, may be made of e.g. metal, of an organic polymeric material (such as e.g. the material available under the trade designation DYNEEMA), and so on. In some embodiments, the composite connector 20 may be attached (often, non-removably attached) to a distal end 7 of safety line 5.

In some embodiments, such a fall-protection safety apparatus 1 may be a self-retracting lifeline (SRL) as depicted in exemplary embodiment in FIG. 1. Ordinary artisans will understand that a self-retracting lifeline comprises a load-bearing safety line (“lifeline”) 5 that can be unwound from a housing 2 which may be secured e.g. by a coupler 3 to an anchorage. A distal end of safety line 5 is connectable by way of connector 20 e.g. to a D-ring 11 of a harness 10. SRL housing 2 comprises a reel (drum) 4, indicated generically in FIG. 1, that is rotatably connected to housing 2, with a proximal end of safety line 5 being attached to reel 4. Safety line 5 can be unwound from reel 4 and thus extended from housing 2 to follow a user as the user moves about, with reel 4 being biased to exert a slight tugging force on safety line 5 so that the reel retracts safety line 5 back into housing 2 and rewinds it onto reel 4 as the user moves toward housing 2. An SRL (e.g. housing 2 and reel 4 thereof) will typically include a brake, e.g. comprising centrifugally-activated pawls that act in cooperation with a ratchet ring. Such a brake will be activated in the event of a user fall (e.g. upon rapid unwinding of safety line 5 from reel 4) to safely bring the user to a halt. In some embodiments a ratchet ring may be fixed in position (e.g., fixed to housing 2). In other embodiments an SRL may comprise a ratchet ring that can rotate at least somewhat if a centrifugally-activated pawl comes into contact with a tooth of the ratchet ring; in such a case the brake will often include one or more pads of frictional material that gradually stop the rotation of the ratchet ring.

In some embodiments, an SRL may comprise a safety line 5 that is equipped with an energy absorber 6 as shown in exemplary embodiment in FIG. 1. In some embodiments, an energy absorber 6 may take the form of a so-called shock-pack or tear-strip. Such energy absorbers often rely on two or more segments of line, e.g. webbing, that are folded into an accordionized (z-folded) arrangement and fastened (e.g. by stitching) to each other, with the segments and fasteners being arranged so that in response to a sufficient force (e.g. in the event of a fall), the fasteners will give way so that the segments separate (e.g. “unzip” and/or unfold) from each other in a manner that absorbs energy to safely bring the user to a more gradual halt than would otherwise occur in the absence of the energy absorber. Such energy absorbers are often used in SRLs that have a fixed ratchet ring and that do not include the above-described pads of frictional material; however, an energy absorber may be used in an SRL of any design. Fall-protection safety apparatus such as self-retracting lifelines and components and functioning thereof are described in various aspects e.g. in U.S. Pat. Nos. 7,843,349, 82,565,74, 8,430,206, 8,430,207, and 9,488,235. In some embodiments an SRL may be a so-called “personal” SRL (described in further detail later herein) that is used in a somewhat different manner than described above. Nevertheless, the arrangements disclosed herein can be used with such an SRL, as discussed later herein. In some embodiments a self-retracting lifeline (whatever the specific design) will be compliant with ANSI standard Z359.14-2021.

### Composite Connector

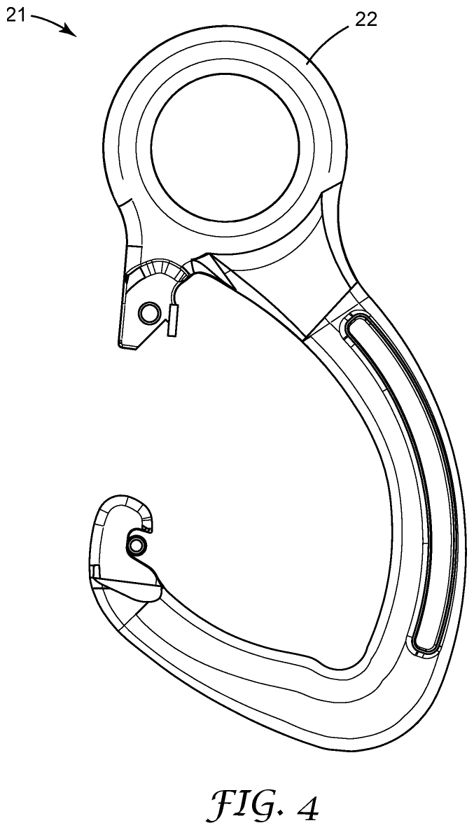

A composite connector 20 is depicted in exemplary embodiment in FIG. 3. By definition, a composite connector 20 will comprise a frame 21 and a shroud 30 that is mounted on the frame. An exemplary frame 21 is shown in isolated view (with shroud 30 and gate 23 omitted) in FIG. 4. In many embodiments, frame 21 is made of metal (e.g. aluminum or steel) and provides structural rigidity to connector 20. Shroud 30 may be made of e.g. a molded organic polymeric material and may serve any of several functions. One such function is to serve as a protective housing for various electronic and/or optoelectronic components as discussed in detail later herein.

Frame 21 and shroud 30 collectively define a connection area 26 as indicated in FIG. 3. By a connection area is meant an area through which a portion of a support item can be passed through so that the support item is “captured” by connector 20 so as to disconnectably connect connector 20 to the support item. In many common embodiments, such a support item will be a D-ring 11 (e.g. a dorsal D-ring) of a fall-protection harness 10 as depicted in FIG. 2. Terms such as inward and outward as used herein will be defined relative to connection area 26; an inward direction is generally toward area 26 and an outward direction is generally away from area 26. Terms such as interior will be specifically used in discussions of components, surfaces, and so on, that are within shroud 30 itself.

The term “connector” as used herein broadly encompasses items commonly referred to as hooks and carabiners; a connector may have any appropriate design. In some embodiments, connector 20 may comprise a generally curved portion (a lower portion, in the orientation depicted in FIG. 3) that is often referred to as a “bowl” of the hook or carabiner. In some embodiments, connector 20 (e.g., frame 21 thereof) may comprise any suitable feature (e.g. an eyelet 22 as in FIG. 3) that allows connector 20 to be removably or non-removably attached to a distal end of a safety line of a fall-protection apparatus. In some embodiments, shroud 30 may only partially encompass frame 21 (as evident from FIG. 3) so that eyelet 22 of frame 21 protrudes outward of shroud 30 so that eyelet 22 can be accessed.

In some embodiments, composite connector 20 will be a gated hook or carabiner (sometimes referred to as a snap hook) as in the exemplary design shown in FIG. 3. Such a gate 23 may comprise a hinged end 24 and a “catch” end 25; the gate can be rotated about the hinge inwardly into connection area 26 (counterclockwise, in the view of FIG. 3) to open the gate to allow a portion of a support item (e.g. a D-ring) to be passed through connection area 26, after which the gate can be counter-rotated (clockwise, in the view of FIG. 3) to close the gate. In some embodiments, the gate 23 may be biased so that it tends to close automatically e.g. after a support item is passed through the gate.

In at least some embodiments, composite connector 20 will be compliant with ANSI standard Z359.12-2019. In some embodiments connector 20 may be a double-action connector (i.e. with a gate that requires at least two consecutive, different actions to open). One category of double-action connectors are so-called twist-lock hooks and carabiners that comprise a gate 23 of the general type depicted in FIG. 3. In such connectors, a locking mechanism 28 of the gate 23 must be twisted (e.g. at least a quarter turn, around an rotation axis aligned with the long axis of the gate) in order to unlock the gate so that the gate can then be opened. In some embodiments, a locking mechanism 28 may be a collar fitted on a portion of the gate (as in the exemplary arrangement of FIG. 3); or, the entirety of the gate may be twistable. Some connectors may be triple-action connectors in which the collar and/or gate must be moved slightly along its long axis, in addition to being rotated, to allow the gate to be opened. Another category of double-action connectors are certain snap hooks (or locking snap hooks) in which a locking mechanism must be moved (e.g. pressed inward or squeezed) before the gate of the hook can be opened. All such items will be considered to be connectors as defined herein, and may be referred to generically as gated hooks.

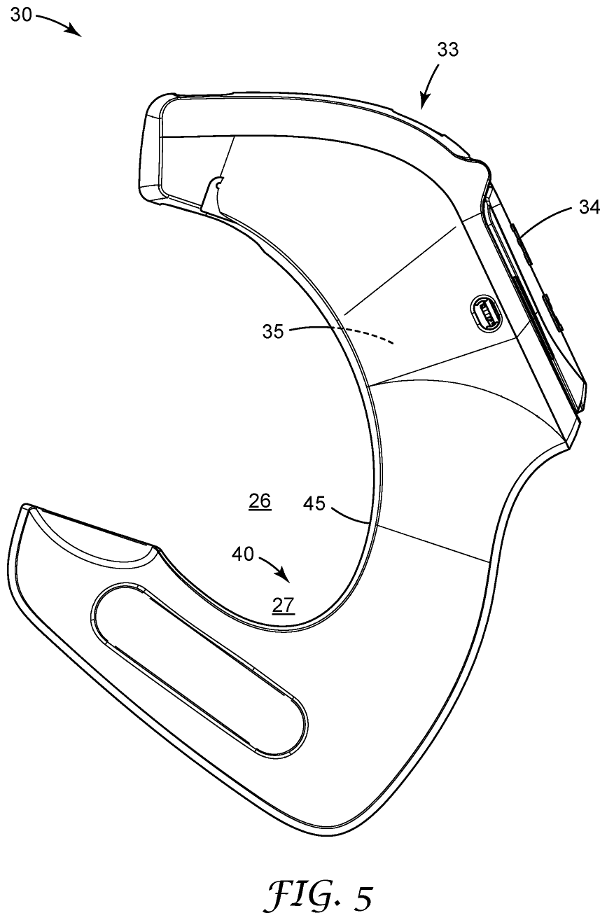

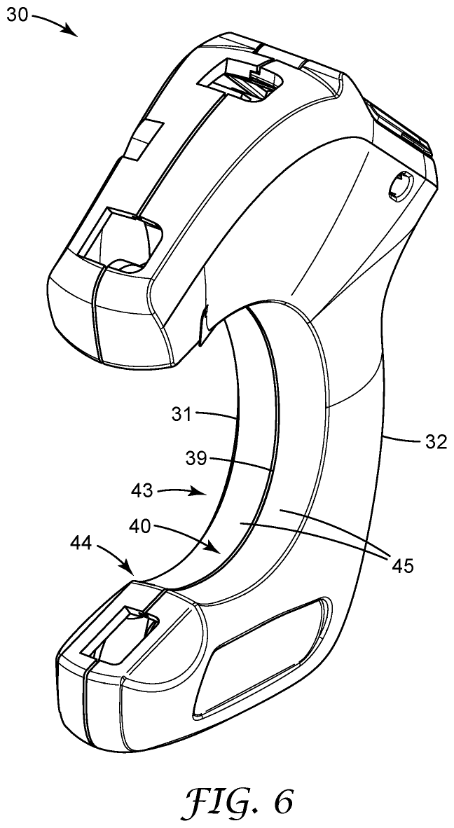

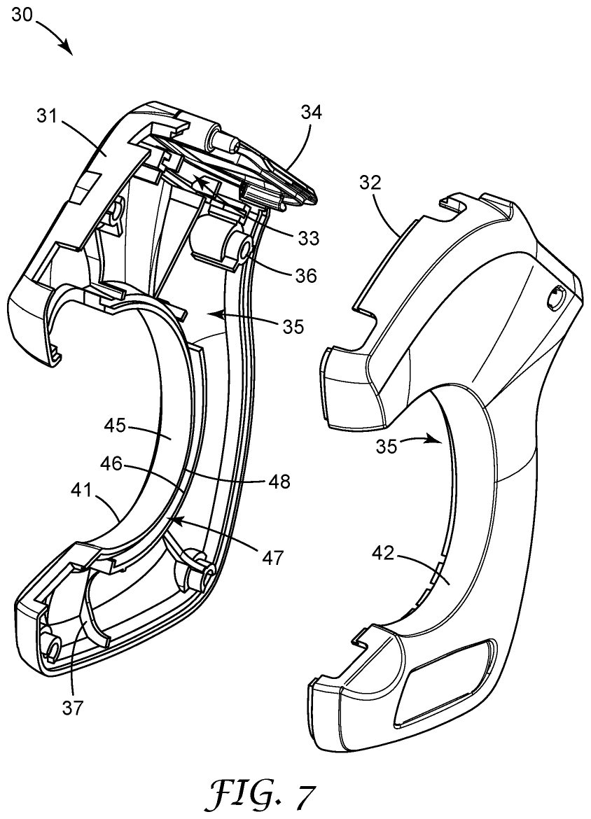

As briefly noted above, shroud 30 can serve any suitable purpose, e.g. to enclose and protect electronic and/or optoelectronic equipment, to provide that connector 20 is more easily graspable, and so on. In some embodiments, a shroud 30 may be non-removably mounted on frame 21, meaning that shroud 30 is not removable from frame 21 in ordinary use of connector 20 (although shroud 30 may be accessed, removed, etc., if connector 20 is to be serviced). In some embodiments shroud 30 may be comprised of first and second shroud pieces 31 and 32 as shown in the exploded view of shroud 30 in FIG. 7. (FIGS. 5 and 6 show side and side-perspective views of shroud 30; in FIGS. 5-7 and in various other Figures herein, items such as frame 21 and gate 23 are omitted so that details of shroud 30 can be more easily seen.) In some embodiments shroud pieces 31 and 32 may be assembled together e.g. by the insertion of various screws, bolts, or the like into various complementary apertures 36 (different ones of which are pointed out in different Figures). Other methods of assembly and/or attachment of shroud pieces may be used. However made, shroud 30 will define an interior volume 35, much of which may be occupied by portions of frame 21. However, other portions of interior volume 35 may provide e.g. an electronics space 33 that can house any suitable items as discussed later herein. Such a space may also provide room for an internal power source, e.g. a battery, which may be accessed by an access door 34 if necessary. In some embodiments an access door may not be necessary, e.g. if the power source is rechargeable (e.g., is a rechargeable battery, a supercapacitor, etc.) and if shroud 30 includes a port by which the battery can be recharged (or if the internal power source is configured for wireless recharging). In some embodiments, first and second shroud pieces 31 and 32 may be major shroud pieces that are roughly similar in size, e.g. meeting to form a junction 39 of inward wall 45 of shroud 30, with junction 39 being approximately transversely centered in shroud 30 as evident in FIG. 6. However, in other embodiments, one shroud piece may be a major piece (and e.g. may provide the majority, or all, of inward wall 45 of shroud 30), with one or more other minor shroud pieces serving e.g. as a “lid” that closes off the remaining area not covered by the major shroud piece.

Ordinary artisans will appreciate that in view of the uses to which connectors of fall-protection apparatus are commonly subjected, a shroud 30 of a composite connector 20 as disclosed herein will need to do more than just, e.g., house and protect electronic components. Rather, a shroud 30 that is arranged in the general manner disclosed herein will frequently come into contact e.g. with portions of a D-ring that the composite connector 20 is connected to. That is, the movement of a wearer of safety harness 10 will cause the D-ring to move relative to connector 20, so that the D-ring may frequently contact, e.g. impinge on, the shroud of the connector. Also, any retraction force applied to the safety line 5 (e.g. of an SRL) to which the connector 20 is attached will tug on the connector and cause the shroud to impinge on the D-ring that the connector is connected to. Moreover, in conditions of use e.g. at a worksite, the distal end of safety line 5, bearing the composite connector, may occasionally be e.g. dropped on a hard surface or impacted by a tool and/or a retraction of the safety line may cause the connector to impinge on the housing 2 of the SRL. In short, even in ordinary use, a connector 20 is subject to fairly strenuous conditions in terms of occasional impacts and the like. (Such connectors are often used outside and so will be subject to environmental conditions, e.g. rain, snow, prolonged sunlight, and so on.) Also, of course, the connector, and thus the shroud, may be subject to considerable forces in the event of a user fall.

Given these considerations, if a connector 20 comprises a shroud 30, the customary practice in the art is that the shroud should be as strong and robust as possible. Such shrouds are often made of materials such as e.g. polybutylene terephthalate, polycarbonate, or some other engineering plastic, and/or is made of materials that are filled with reinforcing fillers such as glass fibers, carbon nanotubes, etc., and/or are provided with internal reinforcing struts or the like. All such measures are to ensure that the shroud is sufficiently durable for use at a worksite, e.g. in construction or industrial use, and is capable of withstanding forces commensurate with ordinary use. Thus, in conventional practice, a shroud of a composite connector of a fall-protection safety apparatus is configured to be strong and non-deformable.

### Deformable Section

The present disclosure departs from this paradigm by purposefully providing shroud 30 of connector 20 with at least one deformable section 40. As indicated in exemplary embodiment e.g. in FIGS. 3, 5, and 6, a deformable section 40 of shroud 30 will be located and configured (e.g. so as to comprise an inward wall 45) so as to at least partially define a portion of the above-described connection area 26 of the connector. By deformable is meant that at least some portion, area, and/or component of section 40 will deform so as to be displaced at least 0.5 mm (from its previous location relative to the other portions of shroud 30) when the portion, area or component of section 40 is subjected to a force that originates from within connection area 26, that is caused by the impinging of a portion of a support item on deformable section 40, and that is in a range characteristic of the forces that are developed on connectors in the course of a fall-arrest. Such fall-arrest forces are typically in the range of e.g. 300-1800 pounds; the ANSI Z359.6 Fall Protection Code for active fall protection systems limits such fall-arrest forces to a maximum of 1800 pounds. Detailed discussions of how a section 40 of a shroud 30 can be rendered deformable are provided later herein. It will be appreciated that in at least some embodiments, some or all other sections of shroud 30 will not be deformable in the manner of section 40, even if those other sections are, e.g., made of the same materials as section 40. It is also noted that any movable items (e.g. switches, buttons, battery-compartment doors, and so on) as may be provided on a shroud 30 in the conventional art, will not be considered to be deformable sections of the shroud in the sense used in this disclosure.

### Interruptible Signal-Transmissive Pathway

Composite connector 20 will comprise a fall-detection module 100 comprising an interruptible signal-transmissive pathway 101 that passes through at least a portion of deformable section 40 of shroud 30. Such arrangements provide that if a user fall occurs, the forces that arise in arresting the fall of the user can cause a portion of a support item to which connector 20 is connected to impinge on the deformable section 40 of shroud 30 with sufficient force as to cause at least some deformation of section 40 of the shroud; this deformation of section 40 can then interrupt the transmission of one or more signals along pathway 101 as discussed in detail later herein. The terminology that the interruptible pathway passes through the deformable section broadly encompasses arrangements in which at least a portion of the pathway extends through the actual deformable material of the deformable section itself, as well as arrangements in which at least a portion of the pathway extends through a space that is closely adjacent to the actual deformable material of the deformable section so that a deformation of the material will cause an interruption in the pathway, according to various examples provided herein.

By way of a specific example, a composite connector 20 may be envisioned that is on the distal end 7 of a safety line 5 of a self-retracting lifeline (SRL) as in the general arrangement depicted in FIG. 1. The housing 2 of the SRL may be mounted overhead of the worker, on a suitable anchorage. The worker will wear a harness 10 of the general type shown in FIG. 2, with composite connector 20 of the SRL connected to a D-ring 11 of the harness. If the user falls downward, the D-ring will tend to travel downward within connection area 26 of the connector, e.g. toward an impingement area generally indicated by reference numeral 27 shown in FIG. 3. When the user fall is arrested by the SRL, a portion of D-ring 11 (e.g. an uppermost portion 12 as shown in FIG. 2) that is at or near impingement area 27 is likely to impinge on deformable section 40 of shroud 30 with enough force to deform at least some portion of deformable section 40.

Deformable section 40 and signal-transmissive pathway 101 are configured so that any such deformation of section 40 will be sufficient to at least temporarily interrupt transmission of a signal along pathway 101. Any such interruption of the signal along pathway 101 can be taken as an indication of a possible user fall. In some embodiments, deformable section 40 may be configured so that any such deformation will be permanent (in such cases, deformable section 40 may be considered to somewhat resemble a so-called “crumple zone” of an automobile). Thus in such cases, deformable section 40 may undergo permanent deformation, e.g. manifested as a permanent change in shape or aspect, in response to a user fall. However, such deformation may not necessarily be very large; in fact, in some instances it may not necessarily be easily observable upon visual inspection. All that is needed is sufficient deformation to interrupt the transmission of a signal along pathway 101. However, in some embodiments deformable section 40 may be configured so that forces commensurate with a user fall will provoke deformation of section 40 that is e.g. permanent and is obvious upon visual inspection. By interruptible is meant that signal-transmissive pathway 101 is purposefully configured so that a deformation of at least some portion of deformable section 40 of shroud 30 in response to an impinging force as described above, will cause a resulting signal, that would otherwise be sent to a signal detector as the result of a signal being transmitted into pathway 101 from a signal source, to not be sent to the signal detector. In one example, a pathway 101 may be interruptible by being breakable so that a physical gap, discontinuity, displacement, positional offset or the like, exists between portions of the pathway that were previously in intimate, signal-transmissive communication with each other. Other approaches and examples are provided later herein.

Deformable section 40 of shroud 30 may be configured so that section 40 will deform upon experiencing a force that is above a predetermined threshold. Such a force threshold may be carefully chosen to fall within the range of forces typically experienced in a fall-arrest. That is, the force that is required to achieve sufficient deformation of section 40 should not be too great (e.g. greater than 1800 pounds) because a fall-arrest event will typically not produce forces of this magnitude. However, the force should not be too low (e.g. less than 300 pounds) because it might render deformable section 40 susceptible to being deformed due to normal worker motion or e.g. if the connector receives rough handling, is dropped on a hard floor, and so on.

The present investigations have indicated that a force threshold in the general range of approximately 600-800 pounds seems to provide the desired functioning (noting that results so far have been obtained in static testing; the appropriate threshold force may need to be adjusted upon performing dynamic testing e.g. involving actual fall arrest). Thus in various embodiments, a force threshold to cause sufficient deformation of at least a portion of a deformable section 40 in such manner as to interrupt a signal-transmissive pathway 101, may be at least 400, 500, 600, 700, or 800 pounds. In further embodiments, such a force threshold should be no more than 1500, 1400, 1300, 1200, 1100, 1000, or 900 pounds.

Any signal-transmissive pathway 101, of any form and relying on any transmission mechanism, passing through any portion of deformable section 40, may be used for the purposes herein, as long as the pathway is interruptible upon deformation of section 40 in a manner that allows the herein-disclosed functioning to be achieved. In some embodiments, such a signal-transmissive pathway may be disposed on an already-present entity (e.g. an interior surface) of shroud 30; for example, such a signal-transmissive pathway may take the form of an electrically-conductive trace disposed on outward surface 48 of inward wall 45 (as identified in FIG. 7) of deformable section 40. In such an arrangement, deformation (e.g. fracturing) of wall 45 in such a manner as to cause at least some local areas of wall 45 to be displaced relative to each other, may be sufficient to cause at least one break in the electrically-conductive trace. Thus in such a case, the interruption of the signal may be caused by a physical break, gap, discontinuity, etc. in the conductive pathway so that the pathway becomes an open circuit. In other embodiments as discussed later herein, it is possible to cause a signal interruption by displacing adjacent segments of signal-transmissive pathway 101 so that they come into contact with each other to cause a short circuit (rather than the pathway breaking to form an open circuit). Either such mechanism, or combinations thereof, may be used for the purposes herein.

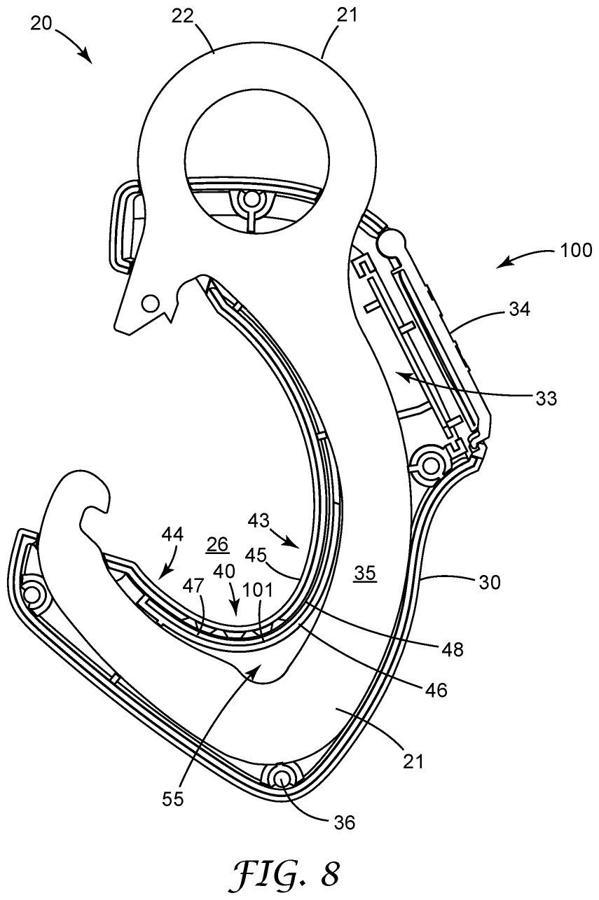

In some embodiments, an interruptible signal-transmissive pathway 101 may reside within a chamber 47 defined within deformable section 40 of shroud 30 in the general manner depicted in FIG. 8 (noting that FIG. 8 is a cross-sectional view in which frame 21 is present). In some such embodiments, the pathway 101 may reside on a substrate (e.g. the pathway may be an electrically-conductive trace on a flex circuit) with the pathway-bearing substrate being inserted into chamber 47. In such an arrangement, deformation (e.g. fracturing) of inward wall 45 and/or outward wall 46 that partially define chamber 47, may cause sufficient displacement to cause at least interruption in the electrically-conductive trace. (If the trace is on a substrate such as a flex circuit, in some instances it may be needed to fracture/break the substrate in order to cause a break in the pathway thereon, as discussed later herein.) Once again, an interruption of the signal may be caused e.g. by a physical break or otherwise-achieved discontinuity in the conductive pathway so that the pathway becomes an open circuit, and/or by a short circuit being formed in the conductive pathway.

Deformable section 40 of shroud 30 may be configured so as to promote the desired deformability, in any suitable manner. For example, the thickness of a member (e.g. inward wall 45) on which a signal-transmissive pathway 101 is located, may be chosen as desired. The materials of which such a wall is made may be likewise chosen as desired, e.g. to have a suitable stiffness, breaking strength, and so on. In some embodiments, a macroscopic cavity may be provided behind (outward of) a portion of a wall to accommodate or otherwise facilitate the deforming of the wall. For example, with reference to FIG. 7, if wall 45 is to be deformable, a chamber 47 behind wall 45 may be provided (as shown in FIG. 7) to allow such deformation. In another example, e.g. if chamber 47 as partially defined by inward and outward walls 45 and 46 is to be deformable, a macroscopic cavity may be provided behind (outward of) at least a portion of outward wall 46 of chamber 47, as exemplified by macroscopic cavity 55 as depicted in FIG. 8. (A macroscopic cavity is defined herein as having a volume of at least 5 cubic millimeters, and will be distinguished from e.g. microscopic voids as present in porous materials and the like.) Such a cavity can be provided by suitably modifying the interior structure of the shroud and/or by modifying the shape of frame 21 that is disposed within the interior of the shroud.

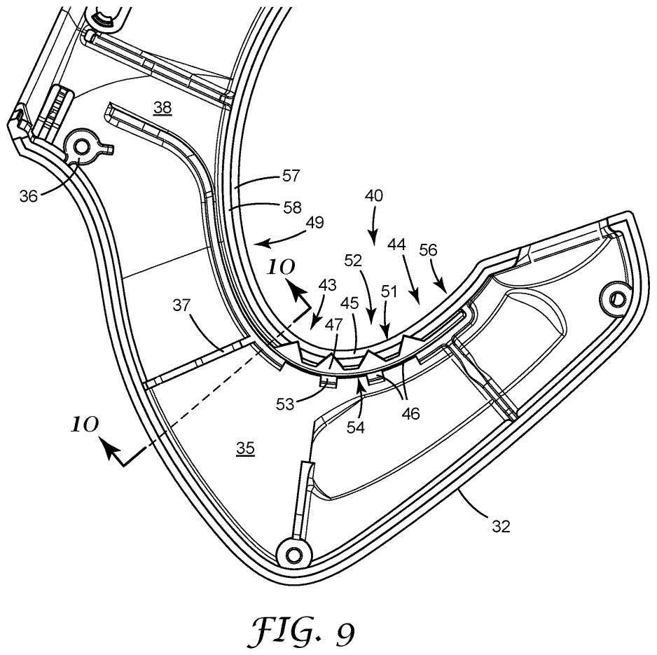

In some embodiments, particular physical and/or geometric features may be provided in various components of deformable section 40 of shroud 30, to promote the desired deformability of at least some areas or constituents of section 40. Some such features are depicted in FIG. 9, which is a cross-sectional view of one major shroud piece 32. For a shroud of a general type shown in FIGS. 6 and 7, similar features may be present in the other major shroud piece 31, with the features of both shroud pieces combining to collectively provide the desired characteristics of deformable section 40.

For example, as depicted in FIG. 9, inward wall 45 exhibits force-concentration structures 51 and zones of weakness 52. The zones of weakness 52 may allow wall 45 to be more easily deformed; the force-concentration structures 51 may allow the deformation force to be brought to bear on local areas of a signal-transmissive pathway that is disposed (e.g. on a substrate such as a flex circuit) within chamber 47. In the depicted embodiment, the zones of weakness 52 take the form of areas of wall 45 that are thinned (in the inward-outward direction) relative to other areas. In the depicted embodiment, the force-concentration structures 51 are in the form of generally pyramidal structures with the narrowed ends facing outward toward the signal-transmissive pathway. Various parameters, e.g. the sharpness of the “tops” of the pyramids (noting that in the orientation shown in FIG. 9 these “tops” are facing generally downward), the spacing of the pyramids, and so on, may be manipulated as desired. In some embodiments, one or more such force-concentration structures may take the form of sharp blade (e.g. representing an extreme case of a sharply narrowed pyramid). As discussed in detail later herein, in some embodiments (e.g. in which an interruptible signal-transmissive pathway 101 is part of an inductive sensing element) the presence of metal may affect the desired inductive sensing; thus, if desired, a blade or the like may be made e.g. of a sufficiently durable non-magnetic material. For example, a ceramic blade may be e.g. embedded in the material (e.g. in a wall) of deformable section 40 at a suitable location.

Also depicted in FIG. 9 are zones of weakness 54 in outward wall 46; these exemplary zones of weakness are areas of wall 46 that are extremely thinned in comparison to other areas 53 of outward wall 46. In the depicted embodiment, the zones of weakness 54 in outward wall 46 are aligned (in the inward-outward direction) with the force-concentration structures 51 of inward wall 45; such arrangements may further enhance the ability of the force-concentration structures to impinge on a signal-transmissive pathway present in chamber 47 in such a way as to break the pathway.

In general, any zones of weakness and/or force-concentration structures may be arranged in deformable section 40 in any desired manner. For example, some such items may extend generally along the long axis of some areas of inward wall 45 of shroud 30, may extend along the transverse direction of some areas of wall 45, and/or may be oriented at any suitable angle in between (e.g., some such items may crisscross portions of deformable section 40). In some embodiments, any such items as are provided both on inward wall 45 and outward wall 46, may be positioned and configured so that the interruptible signal-transmission pathway is subjected to a pinching or shearing action.

In various embodiments, any combination of zones of weakness and/or force-concentration structures may be used in inward wall 45 and/or in outward wall 46, as desired. FIG. 9 depicts an exemplary arrangement in which the various features (zones of weakness, etc.) provide a deformable section 40 with terminal ends located approximately at the locations marked 43 and 44 in FIG. 9. FIG. 9 is provided for purposes of illustrating exemplary features such as force-concentration structures and zones of weakness and does not limit the actual placement or extent of such structures and/or zones. For example, in some embodiments, additional such structures and/or zones may be provided so that the resulting deformable section 40 exhibits terminal ends located for example at the locations marked 49 and 56 in FIG. 9.

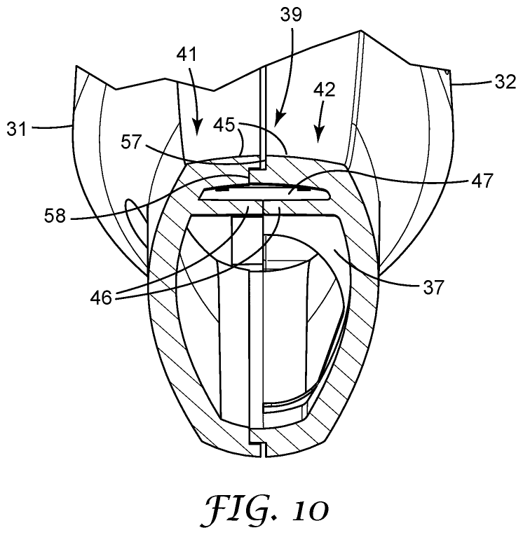

In general, a deformable section 40 of a shroud 30 may occupy any desired angular extent along the inward (connection-area-defining) side of the shroud (e.g. it may provide, or be associated with, any desired angular extent along inward wall 45 of shroud 30). This will be true whether the deformable section is defined at least in part by one or more zones of weakness and/or force-concentration structures, or whether the deformable section lacks any such zones or structures (e.g. so as to resemble the deformable section 40 shown in FIG. 8). In various embodiments, a deformable section 40 of shroud 30 may exhibit an angular extent of at least 30, 50, 70 or 90 degrees. In further embodiments, such a deformable section may exhibit an angular extent of at most 180, 140, 120, or 100 degrees. Such an angular extent may be measured from a vertex that is positioned so as to minimize the variation in the distance from the vertex to all points of the deformable section; such a vertex may be located e.g. near the position occupied by reference numeral 26 in FIGS. 3 and 8. The above-recited angular extents also apply to the interruptible signal-transmissive pathway(s) 101 that pass through deformable section 40. Still other parameters may be manipulated to serve the purposes disclosed herein. Some such parameters can be discussed with reference to FIG. 10, which is a cross-sectional view of a deformable section 40, taken approximately along line 10-10 of FIG. 9. As mentioned previously, in the depicted embodiment shroud 30 is provided by first and second major shroud portions 31 and 32. As evident in FIG. 10, various sections of these shroud portions combine to provide the previously-discussed inward wall 45 and outward wall 46 of deformable section 40 of shroud 30. Specifically, panels 41 and 42 of shroud pieces 31 and 32 combine to form inward wall 45; similarly, panels (unnumbered) of shroud pieces 31 and 32 combine to form outward wall 46.

Various parameters may be manipulated to promote the desired deformability. For example, rather than junction 39 (that extends through deformable section 40 as evident in FIG. 6) between edges of panels 41 and 42 being a simple butt joint, the edges of panels 41 and 42 may be configured to provide an overlapping joint (often referred to as a lap joint) as evident in FIG. 10. In the depicted embodiment, this is achieved by providing panel 42 with an outward lip 58 that fits into a complementary outward recess of panel 41 and by providing panel 42 with an inward recess 57 that accepts an inward lip of panel 41. (Again, the terms inward and outward refer to directions respectively toward connection area 26 and away from connection area 26.) It will be appreciated that the geometric parameters of any such features may be varied so as to increase or decrease the strength of junction/joint 39 to an appropriate range. Obviously, one or more parameters such as the thickness of the various panels, the taper (or absence thereof) of the various panels, and so on, may be set to appropriate values. While in the depicted embodiment of FIG. 10, the junction between the panels that provide outward wall 46 is a simple butt joint, if desired this could similarly be a lap joint, configured to exhibit a desired strength. Still another aspect that may be manipulated is the presence and/or character of any reinforcing buttresses of the type exemplified by buttress 37 of FIG. 10 (noting that this particular buttress is also identified by reference number 37 in FIG. 9). For example, how closely such a buttress 37 is located to deformable section 40, and/or how closely any such buttresses 37 are spaced along deformable section 40, and the parameters (e.g. thickness and so on) of the individual buttresses will affect the amount of impinging force that is needed for deformable section 40 to deform.

In addition to geometric parameters of the general type discussed above, the properties of the materials of deformable section 40, e.g. of the various components, walls, panels, and so on, of deformable section 40, may be chosen appropriately. Parameters that may be manipulated for such purposes can be chosen from, but are not limited to, e.g. material properties such as strength versus weakness, brittleness versus resiliency, the presence or absence of microvoids, porosity, and so on. In some embodiments, the properties of a component of deformable section 40 may be provided by the inherent or intrinsic properties of a material (e.g. a thermoplastic injection-moldable organic polymeric resin) that is used to form the component. In some embodiments, the material properties may be modified by the presence and level of additives such as e.g. reinforcing fillers, impact modifiers, embrittling agents, and so on. Any such additives may serve e.g. to modify the extent to which any energy resulting from an impact on deformable section 40 is absorbed or is dissipated, the extent to which craze propagation does or does not occur, and so on. Such additives may be chosen e.g. in view of their energy-damping or viscoelastic characteristics, among other properties.

A material that is used for deformable section 40 or at least a portion or component thereof, and/or any additives present in the material, may be chosen e.g. to provide that deformable section 40 can exhibit the desired properties (e.g., deformability in response to an impact) across a wide range of temperatures, in view of the fact that a fall protection apparatus may be used outdoors in wintertime or summertime. A material that is used to provide at least a portion or component of deformable section 40 may also be chosen e.g. in view of its ability to prevent ingress of liquid water and/or of water vapor. In general, any such property of a component or portion of deformable section 40 may be achieved by choice of a polymeric material from which the component or portion of section 40 is formed, by the inclusion of one or more additives e.g. to form a polymer composite with desired properties, by the use of multilayer materials in which different layers contribute different desirable properties, and so on.

Any such material properties may be manipulated in concert with any of the various geometric arrangements and relationships discussed herein, to provide that deformable section 40 exhibits the desired properties. In summary, any result-effective parameter(s) may be varied, in combination with any other parameter(s), to configure deformable section 40 so that it will deform appropriately in response to an impinging force that is within a particular range. It will be understood that given the guidance provided herein, one skilled in the art of designing e.g. molded parts, in particular such parts as may be assembled into shrouds, housings, protective covers and the like, will be able to manipulate any or all of the various parameters, features, and so on, mentioned herein, to produce a deformable section that exhibits force-response behavior that is suitable for the purposes disclosed herein.

In some embodiments, any of the various features and arrangements of a deformable section 40 described above may be provided by being molded into a major shroud piece (e.g. piece 31 and/or 32) in the manner evident in FIGS. 9-11. However, in some embodiments, a deformable section 40, including any of the features and arrangements described herein, may be produced as a separately-made module that is then inserted into the remainder of a shroud 30. For example, features of the general type disclosed herein could be incorporated into a separately-molded item that fits into a designated receiving space that is not occupied by any portions or components of major shroud pieces 31 and 32. With such an approach, care should be taken to provide that any such module is properly seated in such a receiving space and is securely attached to the other portions of the shroud. In various embodiments, such a module may be secured in place by mechanical methods (e.g. by screws or bolts), by way of an adhesive, by laser-welding, or any combination of such methods.

### Electrically Conductive Interruptible Signal-Transmissive Pathway

As mentioned earlier herein, in some embodiments an interruptible signal-transmissive pathway 101 may comprise, or take the form of, an electrically-conductive pathway. In some embodiments, such a pathway 101 may take the form of a conductive trace that is disposed on a major interior surface of a component of deformable section 40 of shroud 30. For example, such a pathway 101 may be a trace of conductive ink that is printed e.g. on interior major surface 48 of inward wall 45 of deformable section 40, as noted earlier herein. More generally, such a conductive pathway may be provided by any appropriate method. Such methods may include (in addition to the deposition of conductive ink) e.g. depositing conductive powder and sintering the powder in place to form a conductive trace. In some embodiments, methods that are well-suited for forming conductive pathways on non-planer, curved surfaces may be advantageous. Such methods include e.g. so-called laser-direct structuring, which is particularly well suited for disposing conductive pathways on the surfaces of arcuate injection molded parts.

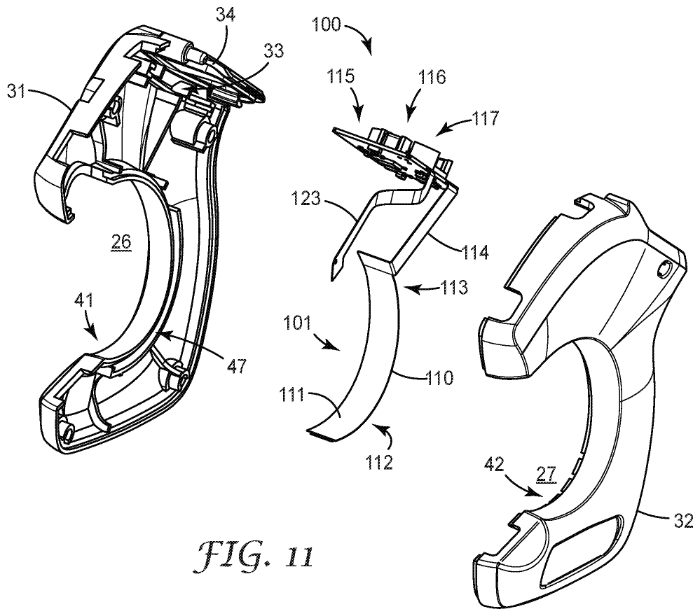

In some embodiments a conductive pathway may be disposed on a substrate that is installed into deformable section 40 (for example, inserted into a chamber 47 defined within deformable section 40). One exemplary arrangement of this general type is depicted in FIG. 11. In FIG. 11, a conductive pathway 101 is disposed on a substrate 110 in the form of a flex circuit. Pathway 101 may be disposed either on an outward surface 111 or an inward surface 112 of flex circuit 110; or portions of the pathway may reside on both. Regardless of whether a conductive pathway is provided directly on a major surface of a shroud component itself, or on a separately-made substrate as with a flex circuit that is then inserted into the shroud, the conductive pathway may be configured to enhance the probability that the pathway will be interrupted (e.g., that the pathway will break to form a gap) upon fracturing and/or displacement of the shroud component and/or substrate on which the pathway is disposed.

In one exemplary arrangement, flex circuit 110, bearing interruptible pathway 101, may be inserted into a chamber 47 as evident from FIG. 11. Electronic components needed to facilitate the operation of pathway 101 may be provided e.g. on a printed circuit (PC) board 115 that is located within an electronics compartment 33 of shroud 30, again as indicated in FIG. 11. Such electronic components can include at least a signal source 116 that is configured to transmit an electrical signal into pathway 101 and a signal detector 117 that is configured to receive a resulting electrical signal from pathway 101, as discussed in further detail later herein. These and any other electronic components may be powered by a battery that is located e.g. in or near electronics compartment 33, e.g. with the battery being in a compartment that is accessible (e.g. if the battery is to be replaced) by way of a battery compartment door 34. PC board 115 may be connected to flex circuit 110 by way of an electrical connector 114 (which may also be a flex circuit). A passage 38 may be provided in shroud 30 (as visible in FIG. 9) to accommodate such an electrical connector 114 (as visible in FIG. 11).

An interruptible signal-transmissive pathway 101 may take any suitable form. In some embodiments, an interruptible signal-transmissive pathway 101, e.g. as provided on a flex circuit 110, may be in the general form of an out-and-back circuit in which pathway 101 extends from a first location (e.g. at a first end of flex circuit 110 that is proximal to electrical connector 114) located generally near first end 43 of deformable section 40, to a second location (e.g. at a second, distal end of flex circuit 110) located generally near second end 44 of deformable section 40, with the pathway then returning to the vicinity of the first location, at or near the proximal end of the electrical connector 114. In other words, the conductive pathway may take the general form of a loop that is e.g. elongated along the long axis of a flex circuit. Such an approach can allow a signal source 116 and a signal detector 117 to be close together (e.g. mounted on a common printed circuit board 115) rather than requiring a signal detector to be positioned at or near the distal end of flex circuit 110. Such an arrangement can advantageously provide that it is not necessary to supply electrical power to a signal detector located e.g. at the distal end of flex circuit 110. Pathway 101 may occupy any suitable portion of flex circuit 110; for example, flex circuit 110 may include an area 113 through which the electrical signals are transmitted, but that may not necessarily be configured to be interruptible in the manner of pathway 101 itself.

A conductive pathway disposed in this general manner, e.g. on a flex circuit, may be made of any suitable material and may take any suitable geometric form. For example, a conductive pathway may take the form of a copper trace that is disposed on a major surface of a flex circuit by any conventional method (e.g. by etching). In some embodiments, it may be advantageous to arrange such a trace to enhance the tendency of the trace to break in the event that the substrate on which the trace is disposed, is fractured or broken. Thus in some embodiments, such a trace may have one or more reduced dimensions. For example, a trace may have a rather small “height” (thickness), e.g. it may have a trace thickness of less than 6, 4 or 2 mils in thickness) and/or trace width. In some embodiments, such a trace may be copper with a trace thickness of e.g. approximately 1.3 mil or even approximately 0.7 mil. If desired, some other conductive material may be chosen e.g. if it is desired for the trace to exhibit greater brittleness than that conventionally exhibited by copper, while still exhibiting sufficient electrical conductivity for the purposes disclosed herein. Substances that may be suitable include e.g. graphite and indium tin oxide.

If the conductive pathway is provided on a substrate (e.g. if the conductive pathway is a conductive trace on a printed circuit board or flex circuit) the substrate may be chosen or modified e.g. so that the substrate does not interfere with the ability of the conductive trace to be broken, and/or so that the substrate itself is easily fractured in such a manner that will cause the conductive trace to be broken. For example, if a conductive trace is borne by a printed circuit board, the thickness of a dielectric layer of the printed circuit board (as well as the material of the dielectric layer) and/or the thickness of a backside copper layer (if present) can be chosen appropriately. In particular, a conductive trace may be provided on a flex circuit made of e.g. polyimide that is e.g. only a few microns in thickness.

Other possible forms for a conductive pathway include conductive wires, conductive filaments (e.g. made of an extruded polymeric material that comprises a suitable loading of a conductive material), and like entities. In general, an interruptible electrically-conductive pathway that is to be used for the purposes disclosed herein may not necessarily need to be extremely conductive; rather, in some cases all that may be needed is the ability to detect the presence or absence of an electrical signal. Thus, for example, rather than being e.g. a copper wire or trace with a resistance of e.g. well under 1.0 Ohm, a conductive pathway may be e.g. an extruded polymeric filament that is loaded with conductive material (e.g. graphite or conductive carbon black) so as to exhibit a resistance of e.g. 10 KOhm. Such a relatively low conductivity pathway may still allow the presence of an electrical signal to be detected. If the pathway is broken, the electrical resistance may sharply increase up to e.g. 10 MOhm or higher (e.g. to an effective value that approaches infinity), so that it is possible to determine that a previously-received electrical signal is no longer being received. So, in some embodiments, an interruptible electrically-conductive pathway that exhibits a rather high resistance (e.g., in comparison to copper) may be used. In some embodiments, one or more particular sections of a conductive trace (or, in general, of any signal-transmissive pathway) can be configured to be more easily deformed, broken, ruptured, and so on, in comparison to one or more other sections of the pathway. This may be done e.g. by making this section of a different (e.g., brittle) material, reducing one or more dimensions of the pathway in this section, and so on. Any such section of a pathway that is configured so as to be particularly susceptible to e.g. rupturing, may be aligned with any of the previously-described force-concentration structures, areas of weakness, and so on, of a deformable section of the shroud, so that deformation/interruption of the pathway is promoted at this particular section. In contrast, any particular areas of a deformable section 40 (or, of shroud 30 in general) that contain e.g. electronic or optoelectronic items or components that would benefit from being protected from impacts and so on, may be preferentially strengthened or reinforced.

An electrical signal that is transmitted into an interruptible pathway 101 may take any suitable form, and may be e.g. intermittent, near-continuous, or continuous. For example, a transmitted electrical signal might be as simple as a voltage that is constantly applied to pathway 101 by a signal source 116. The detection of this voltage by a signal detector 117 will comprise the receiving of a resulting electrical signal, whereas failure to detect this voltage will represent a failure to receive a resulting electrical signal. The signal source 116 may thus be a voltage source and the signal detector 117 may be a voltage detector, e.g. with both being located on a common printed circuit board 115 that is connected to pathway 101 via an electrical connector 114. In some embodiments, electrical signals may be sent into pathway 101 in an intermittent fashion; for example, electrical pulses may be sent into pathway 101 at any desired interval, with a signal detector 117 being configured to detect the presence or absence of a resulting signal that is derived from each electrical pulse.

In various embodiments, a “resulting” signal from an interruptible pathway 101 may take the form of nearly or essentially the exact same electrical signal that is transmitted into pathway 101; or, it may be any electrical signal that is caused by, or derived from, the transmitted electrical signal. In other words, a resulting signal does not have to have the exact same value (e.g. of voltage or current) or character as the transmitted signal; rather, it merely needs to be unambiguous that the resulting signal is caused by, or derived from, the transmitted signal. (The same holds true if the signals are optical signals rather than electrical signals, as discussed later herein.) Discussions later herein will also attest that in some embodiments, the failure (e.g., the ceasing) to receive a resulting signal from an interruptible signal-transmissive pathway may involve receiving an “off-scale” reading, an error message resulting from such a reading, or the like, rather than failing to receive any signal whatsoever. Such cases are encompassed by the herein-disclosed concept of failing to receive a resulting (that is, an expected) signal.

### Fall-Detection Module

An interruptible signal-transmissive pathway 101 that passes through at least a portion of a deformable section 40 of a shroud 30 of a composite connector 20, along with various items and components that are used in combination with pathway 101, will constitute a fall-detection module 100. Items that are used in combination with pathway 101 will include at least one signal source 116 configured to transmit a signal into pathway 101, and at least one signal detector 117 configured to receive a resulting signal from the interruptible signal-transmissive pathway, along with any other items, components (e.g. hardware, software, power source, and so on), and connections therebetween, as needed to obtain data (e.g. the presence or absence of a resulting signal) from the signal-transmissive pathway, to process the data and interpret the data, and so on. Based on the interpretation of the data, the module may registers an indication of a possible fall event. The module may then issue a notification of a possible fall event, as discussed in detail later herein.

In general, fall-detection module 100 can utilize any suitable signal source 116 and signal detector 117, regardless of whether or not the source and detector are e.g. co-located on a common printed circuit board or flex circuit. In some embodiments, the signal source and the signal detector can take the form of one electronic (or optoelectronic) item that is configured to perform both functions. For example, a microcontroller may be configured to send out a signal (e.g. a pulse) and may also be configured to receive any resulting signal e.g. by way of a different input/output pin of the microcontroller. In other embodiments, the signal source and the signal detector may be different entities. For example, the signal source may be a voltage regulator that sends a signal e.g. in the form of a constant voltage that is applied to the conductive pathway, with the signal detector being a microcontroller that is configured to receive a resulting signal by way of detecting the constant voltage as having been returned from the conductive pathway. It will be understood that these and other signal sources and signal detectors that are mentioned herein, are merely representative examples; any suitable source(s) and detector(s) may be used.

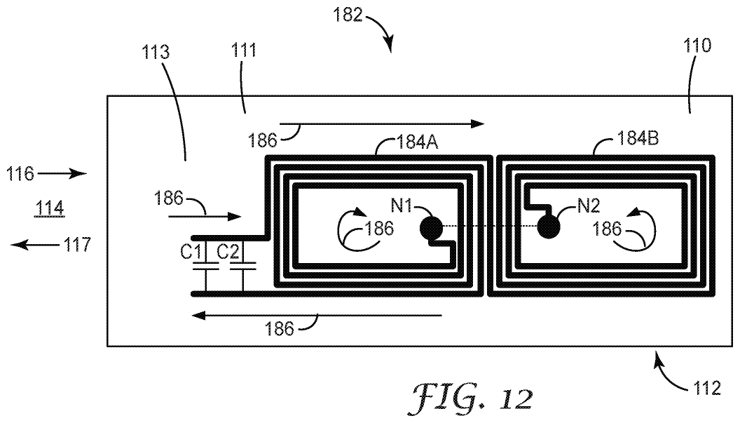

In some embodiments, a signal-transmissive pathway 101 (e.g. an electrically-conductive pathway) can be included in a deformable section 40 of a shroud 30 purely for the purpose of being an interruptible pathway to provide a means to detect a possible user fall. In other words, in some embodiments the primary, or only, purpose of pathway 101 may be to serve as a “tripwire” that can be “broken”, with the breaking of the tripwire indicating a possible user fall. However, in some embodiments an interruptible signal-transmissive pathway 101 may serve at least one other purpose than to detect a user fall. One exemplary arrangement of this type is depicted with reference to FIG. 12. In embodiments of this type, an interruptible pathway 101 (e.g. as provided on a flex circuit in the general manner depicted in FIG. 11) can serve as at least a portion of an inductive sensing element 182 as shown in exemplary embodiment in FIG. 12. Such an inductive sensing element can be used to detect the presence of a metal support item (e.g. a portion of a D-ring of a fall-protection harness) within the previously-described connection area 26 of connector 20. Such a sensing arrangement can allow monitoring of whether or not a wearer of the fall-protection harness appears to be properly “tied-off” to a fall-protection apparatus such as an SRL.

The present investigations have found that a signal-transmissive pathway 101 that is configured to serve e.g. as a coil (or part of a coil) of an inductive sensing element 182 can be interruptible in the case of sufficient deformation of a deformable section 40 within which the coil is disposed. Thus in some embodiments, a signal-transmissive pathway 101 as disclosed herein can do double-duty; e.g. functioning to detect whether a user appears to be properly tied off, and serving to provide an indication of whether the user may have experienced a fall event.

### Inductive Sensing Element

Thus in some embodiments a composite shroud 30 may comprise an inductive sensing unit that relies on at least one inductive sensing element 182. The term inductive sensing unit denotes a device that comprises at least one inductive sensing element along with any other items, components (e.g. hardware, software, and so on), and connections therebetween, to operate the sensing element, to obtain and process data from the sensing element, and so on. In some embodiments such an inductive sensing unit may rely on resonant-frequency-shifting inductive sensing. By this is meant that the inductive sensing unit is configured to detect changes in the resonant frequency of an LC (inductive-capacitive) resonant circuit of an inductive sensing element 182, and to relate any such detected changes in resonant frequency to the presence of a metal support item in connection area 26 of connector 20. Resonant-frequency-shifting inductive sensing is discussed in detail in U.S. Patent Application Publication 2020/0368563 and in U.S. Provisional patent application Ser. No. 17/624912 and in the resulting PCT application published as WO 2021/005467, all of which are incorporated by reference in their entirety herein.

With reference to FIG. 3, in some embodiments inductive sensing to detect whether a support item appears to be present in connection area 26 may operate in conjunction with sensing whether or not a gate 23 of connector 20 is closed, and/or whether gate 23, if closed, is locked in the closed position or not. In some embodiments a gate sensor 121 may be used for such purposes (as indicated generically in FIG. 3). In some embodiments a gate sensor may be e.g. a Hall effect sensor that detects the presence or absence of a magnetic beacon disposed in an appropriate location on the gate; such a gate sensor may be operated e.g. by way of a side-leg electrical connector 123 as shown in FIG. 11. In various embodiments, a gate sensor may detect whether or not a gate 23 is closed and/or whether or not a locking mechanism (as described earlier herein) of the gate is locked. All such arrangements and combinations thereof are encompassed within the concept of a gate sensor detecting whether a gate is “secured” or is “unsecured”. Such arrangements are discussed in detail in the above-cited US '563 and WO '467 publications.

The US '563 and WO '467 publications provide detailed discussions of various ways in which resonant-frequency-shifting inducting sensing may be performed and applied; only a brief summary of those discussions is presented herein. In the depicted exemplary embodiment of FIG. 12, an inductive sensing element 182 is provided in the form of electrical traces arranged into first and second coil segments 184A and 184B. These coil segments are arranged in a generally lemniscate form with the coil segments being wound in opposite directions relative to each other. As discussed in the US '563 and WO '467 publications, such an arrangement may reduce the extent to which external magnetic fields may perturb the operation of the inductive sensor. It will be appreciated that there is a continuous electrical pathway between the two coil segments 184A and 184B depicted in FIG. 12. Connectivity between the two coil segments (e.g. between node NI of coil segment 184A and node N2 of coil segment 184B) can be achieved e.g. by any suitable combination of one or more vias, associated traces, and so on. This connectivity is indicated by the dotted line in FIG. 12 that connects nodes N1 and N2; it will be appreciated that this is a generic representation and that an ordinary artisan with background in the design of inductive sensing elements would understand how to establish such connectivity. It is further noted that the lemniscate arrangement shown in FIG. 12 is merely one representative example of a coil that can be used as part of an inductive sensing element; any such coil or coil segment may be generally in the shape of e.g. a circle, rectangle, square, hexagon, or may be irregular in shape or aspect. In some embodiments multiple coils (each of which may include multiple coil segments) may be present, arranged in any suitable manner.

Those of ordinary skill in the art of designing electrical circuits will recognize that coil segments 184A and 184B, and associated capacitors C1 and C2 as shown in FIG. 12, will provide an LC circuit that, when electrical energy is injected thereinto, will resonate at a particular baseline resonant frequency. The resonant frequency will shift away from this baseline frequency in response to e.g. a metal item being placed in proximity to the coil segment(s). Coil segments 184A and 184B (and also capacitors C1 and C2) can be disposed on a flex circuit 110 (comprising a backing of e.g. polyimide, PEEK, or polyester) that is sufficiently flexible to allow the flex circuit 110 to be curved around at least a portion of connection area 26 of connector 20. (In an arrangement of the general type depicted in FIG. 11, flex circuit 110, bearing inductive sensing element 182 comprising coil segments 184A and 184B, can be curved and inserted into chamber 47.) An electrical current, e.g. as modified by capacitors Cl and C2, can be input into first coil segment 184A travelling in a first (clockwise) direction as indicated in FIG. 12. The current can then pass from node N1 of coil segment 184B to node N2 and can then travel along second coil segment 184B in a second (counterclockwise) direction. The baseline current-voltage characteristics of the circuit will be dictated by the properties of the coil segments, capacitors, and so on, but the actual characteristics (e.g. resonant frequency) that are exhibited will be affected by the presence or absence of any nearby metal.

A signal source 116 and a signal detector 117 may be connected to the inductive sensing unit in the general manner indicated in FIG. 12 so as to inject an electrical current into the sensing unit, to monitor the resonant frequency exhibited by the sensing unit, and so on. In some embodiments a flex circuit 110 may comprise an area 113 that does not comprise a coil or coil segment thereon but rather may comprise other components (e.g. connecting traces, one or more capacitors, and so on) that facilitate the operation of the coil and of the entire inductive sensing element 182. It will be appreciated that such arrangements may be varied in any suitable manner. For example, in some embodiments a coil or coil segment may occupy a greater proportion of the width of the flex circuit (from top to bottom, in FIG. 12) than is depicted in the exemplary arrangement of FIG. 12.

In some embodiments, one or more electrically-conductive traces that are arranged into one or more coils that function as part of an inductive sensing element may be configured so as to be interruptible upon deformation of a deformable section 40 of shroud 30. A signal (or, strictly speaking, an absence of a resulting signal) that results from an interruption due to such a deformation can be distinguished from a signal that results from the presence of a metal item (e.g. a portion of a D-ring) in connection area 26. As discussed in detail in the US '563 and WO '467 publications, the presence of a metal item can change the resonant frequency of the LC circuit an amount that is sufficient to be observable, but with the resonant frequency still remaining within the operating range of the inductive sensing unit. By way of an example, a connector may be equipped with an inductive sensing unit that comprises a baseline resonant frequency in the vicinity of e.g. 4.130 MHz, and comprises an operating range of from e.g. 3.6 MHz to 4.6 MHz. The presence of a metal item may shift this resonant frequency upward to e.g. 4.140 MHz. Such a shift (in this example, approximately 10 kHz) is enough to be observable by the inductive sensing unit, while still remaining within the operating range of the inductive sensing unit.

In contrast, an event such as a breakage (rupture) in a conductive trace of a coil can affect the inductive sensing element in a much more drastic manner. Such a breakage may “detune” the LC circuit of the inductive sensing element so as to shift the resonant frequency of the LC circuit far out of the operating range (in fact, the resonant frequency may approach zero, may approach infinity, or may be essentially undefined). These exemplary scenarios make it clear that in some cases, a “signal” that is received may be e.g. an out-of-range or invalid-reading signal; with this general type of arrangement, the receiving of any such signal, or the receiving of no signal at all, will constitute a failure to receive a “resulting” signal. (In the particular case of resonance frequency monitoring, the system can be configured so that such an occurrence may be readily distinguished from a much smaller shift in resonant frequency that occurs e.g. in response to a nearby metal item.) Moreover, the receiving of any such resulting signal, and/or the failure to receive any such resulting signal, need not necessarily be based on the one-time presence or absence of a single signal. Rather, in some cases, the system may be configured so that the detecting of (or failure to detect) a resulting signal may be performed by detecting the presence or absence of multiple individual signals (e.g. over a period of time). In such cases, the system may e.g. comprise an algorithm that judges whether or not a resulting signal has been detected, based on the number and/or character of multiple individual signals.

The above example attests that in some embodiments one or more electrically-conductive pathways can be configured to perform more than one function. For example, a conductive pathway can serve as a portion (e.g. a coil) of an inductive sensing unit that can provide an indication of a user tie-off, and can also serve as an interruptible pathway that can provide an indication of a possible user fall. It will be noted that a breakage in the conductive pathway (that causes a resulting signal to no longer be detected) does not necessarily have to occur in the coil itself; rather it could be e.g. in a connecting pathway in area 113 of the flex circuit.

The above example allows discussion of another way in which an electrically-conductive signal-transmissive pathway may be affected, i.e. interrupted, by deformation of a deformable section of a shroud. Rather than a break or gap being formed in a formerly-continuous conductive trace as a result of fracturing/displacement of a surface or substrate upon which the conductive trace is disposed, in some embodiments the displacement of a surface on which multiple trace segments are disposed may cause the trace segments to be moved into contact with each other. For example, with reference to the coil of FIG. 12, a sufficient deformation of flex circuit 110 may cause two (or more) parallel, closely-spaced segments of coil segment 184A (or of coil segment 184B) to be forced into contact with each other. Various parameters of an electrically-conductive signal transmissive pathway (e.g. the spacing between nearest-neighbor trace segments) can be chosen so as to enhance the likelihood of the trace segments being forced into contact with each other in the event of deformation of a deformable section of the shroud.

Any such contact between two (or more) such formerly-separated segments of an electrically-conductive pathways can cause a “short” in the conductive pathway that can, for example, drastically change the resonating characteristics of an LC circuit of which the conductive pathway is a part. Such an occurrence may shift the resonant frequency of the LC circuit far out of the operating range (e.g. to zero or infinity). Thus in some embodiments, rather than a signal-transmissive pathway that includes a coil of an inductive sensing element ceasing to send a resulting electrical signal because the inductive sensing element has been drastically detuned by a break in the pathway, the sensing element may cease to send a resulting electrical signal because the sensing element has been drastically detuned by a short-circuit in the pathway.

The above-discussed approach is one in which an interruption in an electrically-conductive signal-transmissive pathway is achieved by causing a “short” in an existing conductive pathway or circuit (e.g. an inductive-sensing coil). This is a particular example of an overall approach in which an interruption is achieved by forming a closed circuit rather than by transforming an existing closed circuit (i.e. that contains a complete path between positive and negative terminals or sources) into an open circuit (that does not have a complete path between positive and negative terminals or sources). Such an approach is not limited to shorting out an existing closed circuit. Rather, any approach in which deformation of a deformable section of the shroud causes a closed circuit to be formed in such a manner as to achieve a signal interruption, can be used.

Thus for example, an arrangement may be used in which a deformation of a deformable section of the shroud causes a new closed circuit to be formed (completed) in such manner as to cause a signal interruption, without necessarily introducing a short into an existing circuit. Such an approach might, for example, rely on two or more conductive traces that, in the absence of any deformation, are dead ends. The traces may be positioned in sufficiently close proximity to each other that deformation of the deformable section of the shroud will cause them to be urged into contact with each other thus forming a closed circuit. All such approaches are encompassed within the disclosures herein. It is noted that an approach in which a formerly-open circuit is closable in this manner may, in some aspects, resemble an approach of providing an electrical switch within the shroud. It is emphasized that any such formation of a closed circuit (indeed, any of the approaches disclosed herein in which a signal is caused to be interrupted) is predicated on the herein-described deformation of a deformable section of the shroud. Given the above-discussed possibilities, the generic terminology of an “interruption” in an electrically-conductive pathway (and, in general, of a signal-transmissive pathway being “interruptible”) is used herein. It will be appreciated that an interruption in an electrical pathway, that is manifested as a failure to return a resulting electrical signal, does not necessarily have to result from a true breakage or gap in the pathway e.g. so as to form an open circuit. Rather, it can result from the pathway being affected in some other way, e.g. by introducing a short circuit that affects the characteristics of the pathway in a drastic way that causes a failure to transmit a resulting electrical signal. Or, it can result from the formation of a new closed circuit that causes a failure to transmit a resulting electrical signal.

The above discussions also illustrate that a resulting signal that is received (or ceases to be received) by a signal detector 117 does not necessarily have to be a simple parameter like e.g. a current or a voltage. Rather, in some embodiments the resulting signal can be a complex parameter that is e.g. derived from a time-varying current-voltage relationship; for example, it can be a resonant frequency exhibited by an LC circuit. It is thus attested that a “resulting” signal as disclosed herein can take any suitable form, as long as a disappearance of the resulting signal results from an interruption in a signal-transmissive pathway. Thus for example, a resulting signal may be e.g. a value of current and/or voltage, a value of a change in current and/or voltage, a value of a resonant frequency of an LC circuit, a change in a value of a resonant frequency, a property of an electrical waveform (e.g., frequency, amplitude, character (e.g. sinusoidal versus sawtoothed) or a change thereof), and so on. The possibilities are not limited to the above list. Also, a failure to receive a resulting signal may take the form of receiving an out-of-range or invalid signal instead of receiving a signal that is within an expected range, as discussed in the above example of a resulting signal that is in the form of a resonant frequency of an LC circuit. Thus it is emphasized that a failure to receive a “resulting” signal (that is, a signal that is expected to be received during normal use of the composite connector, in the absence of a user fall) does not necessarily require that no signal, of any type, must be received.

In some instances an inductive sensing element may be arranged in such a way to enhance the ability of the element to perform inductive sensing. For example, with reference to FIG. 11, in some embodiments an inductive sensing element 182 (e.g. of the general type shown in FIG. 12) may be disposed on a flex circuit 110, with the flex circuit 110 in turn being disposed on an electromagnetic shielding layer (e.g. of a material such as ferrite or the like). Such a shielding layer can minimize any effect of a portion of frame 21 (which is typically made of metal) that underlies the inductive sensing element 182 on the ability of the inductive sensing element to detect a metal support item (e.g. a D-ring) within connection area 26. In some embodiments a layer of adhesive (e.g. pressure-sensitive adhesive) may be present on at least a portion of a major surface 111 or 112 of flex circuit 110 (or on a portion of a shielding layer that is disposed on the flex circuit). Such an adhesive may be used to mount flex circuit 110 securely in place (e.g. within chamber 47) in shroud 30 to ensure that the inductive sensing element is fixed in place relative to the metal frame, which can further minimize any effect of the metal frame on the functioning of the inductive sensing element.

If any such components (including, but not limited to, e.g. a substrate of a flex circuit, an electromagnetic shielding layer such as a ferrite layer, and/or a layer of pressure-sensitive adhesive) are present, and if the conductive trace that provides the inductive sensing element is also serving as an interruptible pathway, the effect of these components on the ability of the conductive trace to be interrupted (e.g. broken, shorted out, etc.) may be taken into account. In some embodiments, such components may be configured so that the conductive pathway can be interrupted without necessarily breaking or severing any other component(s) that may be present. In other embodiments, any or all such components (e.g. a flex circuit substrate, an electromagnetic shielding layer, and/or a pressure-sensitive adhesive layer) may be broken or severed along with the conductive pathway. In some embodiments, at least some such components (e.g. a shielding layer and/or a pressure-sensitive adhesive layer) may be disposed only at such locations at which they can serve most effectively for the above purposes, with the deformable section of the shroud being configured to deform at one or more locations at which such components are not present. For example, a deformable section may be configured to have a force-concentration structure that is aligned e.g. with a local gap in a ferrite electromagnetic shielding layer and/or in an adhesive layer that otherwise underlies the majority of the inductive sensing element.

In the above example, a layer of electromagnetic shielding material (e.g. a ferrite layer) is arranged so that a gap is present in this layer at a location at which it is desired to introduce deformation into a signal-transmissive pathway (e.g. a location at which it is desired to break the pathway). In such an approach, the electromagnetic shielding layer is arranged simply to provide that the layer does not render it difficult to break the pathway at a desired location. However, other arrangements and manipulations of an electromagnetic shielding layer can be envisioned. For example, an electromagnetic shielding layer may be positioned in proximity to a conductive pathway so that any change in the physical form of the shielding layer (e.g. a change in shape, aspect ratio, proximity to the conductive pathway, and so on) can have an effect on the conductive pathway that results in a signal interruption. For example, referring to the previous discussion of a conductive pathway that comprises an inductive-sensing coil, any significant change in the physical form of an electromagnetic shielding layer that is present in proximity to the coil may significantly shift the resonant frequency of the inductive-sensing coil. In one example, deformation of a deformable section of the shroud may cause the electromagnetic shielding layer to be physically shifted further away from the coil and/or into a location at which the layer no longer effectively shields the conductive pathway from nearby metal (e.g. from a metal frame of the connector). Such an occurrence may cause a large shift in the resonance frequency exhibited by the coil and may thus result in a signal interruption of the general type discussed earlier herein. It will be appreciated that any such effect does not necessarily have to involve any deformation of the conductive pathway (e.g., an inductive-sensing coil) itself; that is, it does not necessarily have to involve the conductive pathway being shorted out, being broken to form an open circuit, and so on.

The above example may be generalized as an approach in which a secondary layer is provided in the deformable section of the shroud, the secondary layer being configured so that deformation of the deformable section of the shroud will cause some change in physical form of the secondary layer. This change in the physical form of the secondary layer in turn will affect the ability of the signal-transmissive pathway to transmit a resulting signal in the manner described herein. Although in the above example the secondary layer was an electromagnetic shielding layer (comprising e.g. ferrite), any secondary layer, of any type and that affects the transmission ability of the signal-transmissive pathway through any mechanism, can be used. (In fact, a substrate of a printed circuit board or flex circuit can serve as such a secondary layer and can be tailored to affect the ability of the signal-transmissive pathway to transmit a resulting signal, as discussed earlier herein.) The above discussions also introduce the possibility that deformation of the deformable section of the shroud may cause a conductive pathway (e.g. an inductive-sensing coil) or at least a portion thereof, to e.g. be moved toward a metal object such as a frame and/or to be moved to a location in which the conductive pathway is no longer as effectively shielded by an electromagnetic shielding layer. All such occurrences are also possible mechanisms for interrupting a signal-transmissive pathway and are encompassed within the approaches disclosed herein.

Although discussions above have primarily focused on an electrically-conductive pathway that can serve e.g. as a coil of an inductive sensing element in addition to serving as an interruptible tripwire for purposes of detecting a possible fall, an interruptible pathway may serve any desired purpose. For example, in some embodiments such an interruptible pathway may provide, or include, a coil that serves as an antenna of an RFID tag or of an RFID reader. (In particular embodiments, the interruptible pathway may serve as an antenna of an NFC tag or of an NFC reader.) In more general terms, the interruptible pathway may serve as any portion of the circuitry of an RFID tag or reader. The pathway may be configured so that the functioning of the pathway as an interruptible “tripwire” should not unacceptably interfere with the functioning of the pathway as part of an RFID tag and/or reader.

In general, a pathway that serves as an interruptible tripwire may serve any other purpose in the overall electronic or optoelectronic circuitry of the composite connector. For example, such a pathway may provide for communication of signals, may provide power to any desired component (whether e.g. a sensor, a communication device, a notification device (e.g. an LED that emits visible light)), and so on. It is noted in passing that in various embodiments, any number of interruptible signal-transmissive pathways may be present, e.g. passing through various portions of deformable section 40. In other words, the present arrangements are not limited to a single pathway, or even to two or three such pathways.

### Optical and Other Types of Interruptible Signal-Transmissive Pathways

While discussions so far herein have focused on interruptible signal-transmissive pathways that are electrically conductive so as to allow transmission of electrical signals, the general approach disclosed herein is not limited to transmission of electrical signals. For example, an interruptible signal-transmissive pathway may be an optical pathway, provided e.g. by one or more optical fibers that pass through a deformable section 40 of a shroud. In various embodiments, such an optical fiber or fibers might extend through a designated chamber 47, might be seated in grooves provided in one or more interior surfaces of the shroud, or might be embedded partially or completely within a component (e.g. a wall or partition) of the shroud. Any such arrangements are possible, as long as the optical fiber(s) is able to receive an optical signal transmitted thereinto from a suitable optical signal source, to return a resulting optical signal to a signal detector, and to be broken or otherwise interrupted by deformation of deformable section 40.

While a separately-made optical fiber (e.g. comprising a cladding and a core) is one specific example, optical methods may make use of any arrangement in which a pathway, e.g. a waveguide, is provided along which an optical signal may be transmitted. Such a waveguide may take any suitable form; for example in some embodiments it may be a light pipe. Optical signals may be introduced into such a waveguide and received from such a waveguide, through any of the well-known means that are available. Any such arrangements may make use of various optoelectronic components, sources, detectors, and so on, as are widely available. In similar manner as discussed earlier herein for electrical signals, in various embodiments an optical signal may take the form of a continuous beam or may take the form of pulses or otherwise intermittently-transmitted signals. Again in similar manner as with electrical signals, an optically-based system may be configured so that the optical detector is located proximate the optical source (rather than having to position an optical detector at the far end of the deformable section of the shroud). This may be achieved e.g. by arranging the optical pathway in a loop that makes a round-trip to the far end of the deformable section and back (for example by using an optical fiber or fibers that can be bent to a sufficiently small radius of curvature to allow them to make a “U-turn” at the far end of the deformable section). Another possibility is to equip an optical pathway with an optically reflective or retroreflective item at the far end of the optical pathway, so that (e.g. when using pulsed or intermittent signals) a signal can be transmitted into the optical pathway, after which the presence or absence of a reflected, resulting signal can be detected.

In some embodiments, an interruptible optical pathway need not necessarily take the form of a pathway (e.g. a waveguide) that is defined or bounded in large part by actual physical surfaces. Thus for example, an interruptible pathway could take the form of an optical train established e.g. by one or more reflectors, partial reflectors, or the like, with a signal source (e.g. a laser diode) being configured to send an optical signal into the pathway and with a signal detector being configured to detect any resulting signal from the pathway. In the simplest case, such an interruptible pathway might take the form of a signal source and a signal detector without any reflectors or like devices (e.g. so that the signal detector is positioned line-of-sight to the signal generator).

Whatever the specific design, such a pathway may be interruptible in any suitable way. For example, the deforming of at least a portion of deformable section 40 can cause the portion to enter the optical pathway so as to physically block the pathway. In such a case, the portion may advantageously be sufficiently non-transmissive to the particular optical signal that is used that the portion can block the signal, whether e.g. by absorbing, scattering, or some combination thereof. Or, the deforming of at least a portion of deformable section 40 can cause a reflector to become misaligned from the previously-existing pathway. Any such arrangement or combination thereof may be suitably employed.

Any combination of any of the arrangements disclosed herein may be envisioned. For example, a composite connector (e.g., a deformable section thereof) may be equipped with an electrical circuit that provides an inductive sensing element, along with the deformable section also comprising an optically-transmissive pathway that serves as a tripwire for purposes of detecting possible fall events. Still other arrangements are possible, e.g. in regard to the nature of a resulting signal that is, or is not, received by a signal detector. For example, an interruptible signal-transmissive pathway may include, or otherwise be predicated on the presence of, a “beacon” that e.g. periodically issues a signal (whether e.g. electrical or optical) that can be received by a signal detector. In such a case, the interruptible pathway may comprise e.g. a conductive pathway by which electrical power is provided to the beacon, with this electrical power serving as a signal that is transmitted into the interruptible pathway and with the power source serving as the source of the signal. A deformation of at least a portion of deformable section 40 may cause an interruption in this conductive pathway, so that the beacon is no longer supplied with power and thus no longer issues a signal. The absence of an expected signal from the beacon can thus be equated with the failure to receive a resulting signal from the interruptible pathway. In general, any action that is caused by a deformation of at least a portion of deformable section 40, and that causes a beacon or like item to be unable to issue a signal (or that causes a signal that is issued by the beacon to not be detectable by a signal detector), can serve this purpose. This once again illustrates that many arrangements are possible, that an interruptible pathway need not take the form of a single pathway based upon a single transmission mechanism, and that a resulting signal that is received or not received from an interruptible pathway, need not necessarily be of the same character as a signal that is transmitted into the interruptible pathway.

### Other Arrangements

Still other arrangements may be envisioned that fall within the scope of the herein-described approach in which a deformation of a deformable section of a shroud of a composite connector causes an indication of a possible fall event to be registered. Such arrangements may rely e.g. on one or more suitable sensors that are positioned and configured so that a sufficient deformation of the deformable section will affect the sensor in a manner that causes a resulting signal to not be transmitted. Suitable types of sensors may include a so-called force-sensitive resistor (FSR) whose electrical resistance changes according to a force that is experienced by the resistor, or a force-sensitive capacitor whose capacitance varies according to a force experienced by the capacitor. A deformation of the deformable section of the shroud can sufficiently affect the resistance of the FSR that, for example, a current that is passed through the FSR changes significantly. The deformation may cause the current to increase or to decrease; any deviation from the expected, baseline current (as detected by a signal detector) can be considered to constitute a failure to receive an expected resulting signal. (Again, any such signal will not depend merely on a transmission of force through the deformable section of the shroud but will be predicated on at least some actual deformation of the deformable section of the shroud.) Similarly, any deformation of a force-sensitive capacitor may cause the nature or aspect of an electrical condition, wave or impulse that is present in a circuit that includes the force-sensitive capacitor, to be altered in a way that causes a failure to receive an expected resulting signal.

A somewhat similar arrangement may make use of e.g. a magnetoresistance sensor. Various types of such devices are available, e.g. tunnel-magnetoresistance sensors, anisotropic magnetoresistance sensors, and giant magnetoresistance sensors. In general, a sufficient change in the magnetic field experienced by any such device will cause a change in the electrical resistance of the device. Such a functionality can be leveraged for the purposes desired herein e.g. by including one or more magnetic entities (e.g. ferromagnetic beads, pellets or wires) in or on the deformable section of the shroud. Any deformation of this section can thus change the position of the magnetic entities relative to the magnetoresistance sensor, which can in turn affect the resistance exhibited by the sensor, so that, for example, a deviation from a baseline current may be caused by such deformation.

In still another example, a somewhat related arrangement may rely on magnetic sensing. For example, a magnetic sensor (e.g. a Hall effect sensor or, in general, a magnetometer) may be maintained in a specified relationship with (e.g., positioned at a specified distance from) one or more magnetic beacons located on or in the deformable section of the shroud. Any deformation that causes the magnetic beacon(s) to be moved relative to the magnetic sensor can be detected by the magnetic sensor and thus can cause a signal to cease to be emitted by the magnetic sensor. Or, in some embodiments, the deformation can cause a new and/or different signal to be emitted by the magnetic sensor. (In view of these possibilities, it is stipulated that in some cases, the failure to receive an resulting signal from a signal-transmissive pathway can involve detecting a new or different signal.) Any suitable number of magnetic sensors and/or magnet beacons can be used.

### Types and Uses of Fall-Protection Apparatus

Discussions so far herein have primarily concerned self-retracting lifelines (SRLs) of the general type shown in FIG. 1; comprising a housing 2 that is attachable to an overhead anchorage and that comprises a safety line 5 that is extendable from the housing, with the distal end 7 of the safety line comprising a composite connector 20 that can be connected to a D-ring 11 of a harness 10 worn by a worker at a worksite, a user of an aerial lift, etc. (Such an SRL will be referred to as a “standard” SRL; this terminology is used purely for convenience of description herein.) However, the arrangements disclosed herein can also be used with a so-called personal SRL. By this is meant an SRL that comprises a housing that is attached to the harness of a user and that comprises a safety line that is extendable from the housing, with the distal end of the safety line bearing a composite connector that can be attached to a suitable anchorage. In other words, the housing of a “standard” SRL is typically secured to an anchorage, often an overhead anchorage (e.g. of a worksite, an aerial lift, etc.) rather than to the user's harness. The housing of a “standard” SRL thus usually remains in the same general location whereas the housing of a “personal” SRL moves with the user.

A composite connector 20 comprising a deformable section 40, an interruptible signal-transmissive pathway 101, and so on, as disclosed herein, may be used with a fall-protection apparatus that is a personal SRL (e.g. that is installed on an aerial lift), in generally similar manner as described herein for e.g. overhead-mounted SRLS. In consideration of the use of the herein-disclosed arrangements with a personal SRL, it is stipulated that the terminology of a “support item” that can be passed through a connection area 26 of a composite connector 20 (and that can impinge on a deformable section of a shroud of the connector, and that can be detected by an inductive sensing unit if such a unit is present), is not limited to the previously-discussed D-rings and the like. Rather, in some embodiments (e.g. in particular when using a personal SRL), such a support item may be any suitable anchorage.

In some instances, a fall-protection harness may be equipped with two such personal SRLs (often referred to as a twin-leg, double-leg, or 100% tie-off arrangement). In such a case, the connectors of both SRLs may be equipped with a deformable section 40, detection module 100, and so on. In some embodiments the two detection modules may operate (and, e.g., issue a fall alert) independently; or, in some embodiments the two detection modules may be able to communicate with each other to at least some extent.

An anchorage may be e.g. any sufficiently strong item or component at a worksite or the like. An anchorage may fall into e.g. two broad categories. The first category encompasses items that are conventionally present and that comprise appropriate geometry and physical strength to serve as an anchorage for a safety line of a fall-protection apparatus, and that have at least one function beyond serving as a potential anchorage for a safety line. Such items are often structural members or combinations of structural members; non-limiting examples of such items include e.g. rebar, tubing (of scaffolding; girders, struts, posts, columns or beams (e.g. of a tower, bridge or the like); safety rails, and so on. A second category of anchorage is a dedicated item that is installed specifically to serve as an anchorage for use with a fall-protection apparatus. Such an item will be termed a dedicated anchorage. In various embodiments, a dedicated worksite anchorage may be a permanently installed item (and may e.g. be fixed in a particular place rather than being portable) or may be a temporarily installed item (and may be portable). Such items include products variously termed steel plate anchors, drop-through anchors, fixed beam anchors, sliding beam anchors, concrete wedge anchors, toggle anchors, concrete D-ring anchors, concrete detent anchors, roof top anchors, anchor straps, and so on. In some embodiments a composite connector as disclosed herein may be used with a fall-protection apparatus (whether a “standard” SRL, or a personal SRL) that is installed on an aerial lift (e.g. an order picker). In such cases, an anchorage can be any suitable structural component of the aerial lift or any suitable item that is attached to the aerial lift (noting again that with a “standard” SRL, the housing of the SRL will be attached to the anchorage e.g. via a coupler, whereas with a “personal” SRL, the housing of the SRL will be attached to the user's harness with the composite connector of the SRL being attached to the anchorage). Further details of fall-protection apparatus suitable for use with aerial lifts and the like (for example, the use of sensing arrangements to detect tie-off of an operator of an aerial lift, the interlocking of an aerial lift with a fall-protection apparatus, the wide variety of types of aerial lifts with which such apparatus may be used, and so on) are found e.g. in U.S. Patent Application Publication 2022/0134149 and in U.S. Provisional Patent Application 63/306548, both of which are incorporated by reference in their entirety herein.

In many embodiments, a deformable section 40 of a shroud 30 of a composite connector 20 may be configured so that any deformation of section 40 that occurs e.g. as the result of a fall event, will be permanent. However, in some embodiments, a deformable section 40 may be configured so that any deformation that occurs (e.g. unless it is the result of an extremely high force that is out of the scope of the present disclosure) may be non-permanent. This can be provided e.g. by equipping at least deformable section 40 of shroud 30 with a suitably resilient material. Such a resilient material may be e.g. at least somewhat elastomeric and/or compressible, as long as the material nevertheless is sufficiently strong and durable to withstand the ordinary treatment that a connector 20 receives e.g. during use at a worksite, on an aerial lift, or the like. A deformable section 40 that is defined herein as “non-permanently” deformable will not exhibit any change in dimension or aspect that is more than 0.5 mm in magnitude, and will not exhibit any visually observable damage or change, after undergoing a fall event.

In some embodiments, a deformable section 40 may be comprised of multiple components, one or more of which are permanently deformable (e.g. fracturable and/or crushable) and one or more of which are e.g. resilient (e.g., with a Shore A hardness of 20-80) so as to not be permanently deformable. (These characterizations are understood to be applicable when the items are subjected to the previously-described range of forces that are encountered in fall event.) For example, a deformable section 40 may resemble the exemplary arrangement of FIG. 7, with walls 45 and 46 of deformable section 40 being made of a material that is rather brittle, crushable, or the like, but with a resilient covering (e.g. a rubberized or elastomeric layer) being disposed over the inward side of section 40. Such an arrangement may still provide the desired functioning (e.g. the presence of the resilient cushion will not prevent walls 45 and/or 46 from being permanently deformed in the event of a user fall). Such a case will be considered to fall in the category of section 40 being permanently deformable. Any such compliant covering may be e.g. overmolded over section 40, or installed as a snug-fitting elastomeric sleeve, or similar arrangement. Such arrangements also serve as specific examples of a general approach in which a deformable section 40 can be configured so that the deformation does not result in any portion or fragment of deformable section 40 being completely liberated from shroud 30 so as to e.g. generate debris. It will be appreciated that there can be multiple ways of achieving such arrangements.

As noted earlier, a deformable section 40 that has an interruptible signal-transmissive pathway 101 associated therewith will be located so as to define at least a portion of connection area 26 as depicted in FIG. 3. By definition, the arrangements disclosed herein do not involve any monitoring of any deformation of e.g. eyelet 22 of frame 21 (as seen e.g. in FIG. 3). It is also noted that the arrangements disclosed herein rely on fall-arrest forces causing actual deformation of deformable section 40 of shroud 30 (which in turn causes an interruption in a signal-transmissive pathway). Such arrangements differ from arrangements in which a shroud or similar component merely is subject to a force (e.g. an impinging force) and transmits the force without any deformation of the shroud. The arrangements disclosed herein thus differ from arrangements in which e.g. the force on a connector or a portion thereof is monitored and the possibility of a fall event is evaluated based on the force or some parameter associated therewith, rather than based on any actual outcome (e.g. the fracturing of a deformable section, resulting in the interruption of a signal-transmissive pathway) that results from the presence of the force.

Discussions earlier herein included a description of an exemplary arrangement in which an electrically-conductive pathway may serve “double-duty” as both an inductive sensing element and an interruptible pathway for purposes of providing an indication of a possible fall. However, many other arrangements are possible, involving any number of signal-transmissive pathways. For example, in some embodiments a composite shroud 30 may be equipped with a first electrically-conductive pathway that passes through at least a portion of the deformable section of the shroud and that serves only as an interruptible pathway to provide an indication of a possible fall. The shroud may further comprise a second electrically-conductive pathway that serves to provide a coil (or a portion or coil segment) of an inductive sensing element. In some embodiments, at least a portion of this second pathway may pass through at least a portion of the deformable section of the shroud so that this second pathway can also serve as an interruptible pathway to provide an indication of a possible fall. A fall-detection module may be configured to take into account signals (or the lack thereof) from both pathways in assessing the possibility that a fall event may have occurred. With such approaches, various arrangements are possible. In some such arrangements, whether a possible-fall notification is issued, or the nature of such a notification, may be chosen as a function of a combination of signals from multiple pathways. For example, the failure to detect a resulting signal from a first pathway, but not from a second pathway, may cause a lower-tier registration of a possible fall event, while a failure to detect a resulting signal from either pathway may trigger a higher-tier registration of a possible fall event.

In any arrangement involving e.g. a first conductive pathway that provides inductive sensing and one or more second conductive pathways that are interruptible in order to provide an indication of a possible fall, the latter pathway(s) should be configured so to not interfere with the functioning of the inductive sensing pathway. For example, a second pathway should not have any significant effect on the resonant frequency of the first, inductive-sensing pathway. This can be facilitated e.g. by ensuring that the impedance and/or resistance of the second pathway differs from that of the first pathway to a large extent. For example, the second pathway may exhibit a fairly high electrical resistance (e.g. 10 KOhm) in comparison to the first pathway. In fact, even if the second pathway exhibits a fairly low electrical resistance (e.g. is in the form of a copper wire or trace) a resistive element may be positioned in series with the second pathway so that the overall resistance of the second pathway is such that it has no significant effect on the first pathway.

The previously-presented scenario in which two conductive pathways are present, one being purely an interruptible pathway for detection of a possible fall, and another that is used for inductive sensing but is also interruptible so as to be used for detection of a possible fall, is a specific example of a general approach in which multiple signals, e.g. from multiple pathways and/or derived from different mechanisms, can be used in assessing the possibility that a fall event has occurred. Various arrangements are possible within this general approach. For example, a first, electrically-conductive pathway may be provided that is interruptible so as to be used for detection of a possible fall (and that may also be configured to be used for inductive sensing); in addition to this, a second interruptible pathway may be provided that is an optically-transmissive pathway (e.g. in the form of one or more optical fibers). Of course, two (or more) similar pathways may be used for detection of possible fall events, e.g. two electrically-conductive pathways or two optically-transmissive pathways. Any such pathways may be independent, e.g. arranged in parallel and/or passing through different portions of deformable section 40 of shroud 30, so that multiple, independent indications of a possible fall event may be obtained therefrom.

Thus in some embodiments, multiple (e.g. two, three, four, or more) signals, e.g. from independent pathways, may be taken into account when assessing the possibility of a fall event. In any such arrangement, the multiple signals may be taken into account (e.g. by processing circuitry of the fall-detection module, that receives the information from the various pathways) in any suitable way. For example, the failure to detect a resulting signal from a small number of pathways may trigger a lower-tier registration (and/or notification) of a possible fall event, while a failure to detect a resulting signal from a higher number of pathways (or from one or more specific pathways) may trigger a higher-tier registration and/or notification of a possible fall event. To facilitate this, the processing circuitry of the fall-detection module (e.g. as resident on a microprocessor mounted on a previously-described printed circuit board) may be equipped with any suitable hardware, firmware, software, and so on. For example, the processing circuitry might include appropriate Boolean logic and/or may rely on one or more of truth tables, logic gates, decision trees, and so on.

Various other enhancements are possible. For example, a fall-detection module may be configured so that it observes a short waiting period before reporting a possible fall event. Thus, for example, if a resulting signal ceases to be detected by a signal detector, the module may wait a short period of time (e.g. no more than a few seconds) before taking any action, to see if the signal is reacquired. Such arrangements may allow occasional data or communication dropouts to be distinguished from a possible fall event. In another example, in some embodiments a failure to detect a resulting signal from an interruptible signal-transmissive pathway upon initial start-up of a fall-detection module may be treated somewhat differently than a failure that occurs during a period of use. In this regard, it is noted that the initial start-up of a fall-detection module may often occur along with the initial start-up and self-check of the entire electronics package of a connector, e.g. when use of the fall-protection apparatus begins. Such initial checks are often performed with electronic apparatus and are often referred to as a power-on-self-test (POST) procedure.

This being the case, the failure to detect a resulting signal from an interruptible signal-transmissive pathway may be evaluated in view of the particular circumstances (e.g. during initial start-up versus during use) and in view of other information received from other electronic components of the connector. For example, if an initial POST procedure reveals not only a failure to detect a resulting signal from the signal-transmissive pathway in the fall-detection module, but also that one or more self-checks of the connector electronics indicate some other anomaly, the processing circuitry may handle the situation differently than otherwise. For example, some other type of notification (e.g., “system not ready”, “possible maintenance required”, or the like) may be issued. Again, the processing circuitry may be set up to include appropriate Boolean logic and/or may rely on one or more of truth tables, logic gates, decision trees, and so on, for these purposes.

In some embodiments, information may be taken into account from one or more sensing systems other than an interruptible signal-transmissive pathway, in obtaining an indication of a possible fall event. For example, in some embodiments a fall detection module may receive information from a sensing system that comprises an accelerometer. Such a sensing system may provide independent information as to forces, accelerations, or the like that have been encountered by connector 20 and that may provide further information as to whether a fall event is likely to have occurred. Such information may be used (e.g. as a secondary indication) in combination with the above-described interruption of resulting signals from a deformable section of the connector (e.g. as a first indication). The term accelerometer is used in general and encompasses e.g. single-axis accelerometers, multi-axis accelerometers, inertial measurement units (which may provide information for up to e.g. six or even nine axes of orientation), and so on. Other items that may be present include e.g. one or more magnetometers, gyroscopes, inclinometers, and so on.

Thus in some embodiments, multiple (e.g. two, three, four, or more) signals, one or more in the form of the presence or absence of a returned signal from one or more interruptible signal-transmissive pathways, and one or more from separate systems such as e.g. an accelerometer, may be taken into account when assessing the possibility of a fall event. Once again, the multiple signals may be taken into account in any suitable way (e.g., the fall-detection module may rely on appropriate Boolean logic and/or one or more of truth tables, logic gates, decision trees, and so on). Thus in some embodiments, arrangements that rely on two (or more) sources of information may further enhance the functioning discussed herein. It is emphasized however that such arrangements can merely provide further enhancements; an arrangement that e.g. relies on a single source of information (e.g. an interruption in a signal-transmissive pathway) is expected to be useful for the purposes and objects disclosed herein. Notifications Based at least on a failure of a resulting signal to be received from an interruptible signal-transmissive pathway, a fall-detection module may register an indication of a possible fall event. As discussed above, in some embodiments this may lead to the issuance of a notification of a possible fall event. Or, in some embodiments, other information (e.g. from an accelerometer) may be considered before logic circuits of the fall-detection module decide whether to issue a notification of a possible fall event. If a notification of a possible fall-event is issued, it may take any suitable form. The term notification broadly embraces any method or mechanism by which one or more persons and/or monitoring entities (whether in close proximity, or not in close proximity but at the same building or worksite, or at a remote location), and so on, may be apprised of a possible fall event. Such a notification may be presented in any suitable way.

In some embodiments, a notification may take the form of, or include, a visible notification and/or an audible notification (e.g. an alarm) broadcast e.g. by the connector itself. In many embodiments, it may be desired to send a notification in a manner that ensures it is received by a person (or, in general, a monitoring entity) other than (or in addition to) the user that has (possibly) fallen. Thus for example, a notification may be sent to a mobile device such as a cell phone (worn e.g. by a safety manager at a worksite), or to a central monitoring location. Such a notification may be sent in any suitable manner, e.g. via cellular telephone, by short-range wireless methods such as Bluetooth or Bluetooth Low Energy, over a local Wi-Fi network, and so on. Various communication methods and arrangements, any of which may be used in combination with the disclosures herein, are disclosed e.g. in U.S. Patent Application Publication 2022/0134149 and in U.S. Provisional Patent Application 63/306548, both of which are incorporated by reference in their entirety herein as noted previously. In this regard, it is noted that in some embodiments, any settings and configurations of the processing circuitry of a fall-detection module may be pre-installed and unchangeable. In other embodiments, at least some such settings may be user-selectable and/or may be updated e.g. by way of a firmware update that may be received e.g. over any suitable communication network.

In some embodiments a notification of a possible fall event that is sent e.g. to a worksite safety manager and/or a central monitoring station may contain information such as an indication that a fall event may have occurred, information sufficient to identify the serial number of the connector and fall module that is reporting the possible fall event, the identify of the worker associated with that connector and so on. In some embodiments, any such notification may include additional information about the possible fall event, about the person that experienced the possible fall event, about the location of the possible fall event, and so on. Any such information may be included as part of, or along with, the notification. Such information may include e.g. information about the force generated in the fall event, the location of the fallen person, and so on. In some embodiments, worker attributes (e.g. their identity, location, height above floor or ground level, and so on) may already be monitored by a telemetry system. In such a system used, a notification of a possible fall event can be correlated with the particular worker that the notification corresponds to, and additional information regarding that worker (e.g. the worker's identity, location, and so on) can be provided by the telemetry system. A possible-fall event notification arrangement as disclosed herein can thus be used in concert with a telemetry system if desired.

In some embodiments, a fall-detection module may be configured with (in addition to the fall-detection and possible-fall-notification functionality described herein) a manually actuatable fall-notification capability. Such a feature may take the form of e.g. a button or switch that can be actuated by a person if the person has fallen and is not certain whether a possible-fall notification has already been sent by the fall-detection module based on a herein-described interruption in a signal-transmissive pathway. Such a functionality may provide a useful secondary method of providing a fall notification and/or may be used e.g. if a person is a non-fall emergency situation in need of assistance. Any such button, switch or the like, may be positioned and configured to minimize the likelihood of it being actuated inadvertently. In some embodiments, the triggering of a possible-fall-event notification in the manner described herein (i.e. based on an interruption in a signal-transmissive pathway) may also cause an audible and/or visual signal to be locally emitted that indicates that a possible-fall-notification has been transmitted (e.g. to a central monitoring station). This can allow a fallen person to be made aware that a possible-fall-notification has already been transmitted and that there is no need to transmit a manually-triggered fall alert signal. However, in some embodiments, such a manually actuatable capability may nevertheless be actuated even if a possible-fall notification has already been sent; this might be done e.g. to confirm that a fall has indeed occurred, to indicate that the fallen person is conscious, or for some other reason.

In general, the arrangements disclosed herein may be used with a wide variety of fall-protection apparatus, methods and systems and can be implemented in a variety of ways. Fall-protection apparatus and systems (e.g. lanyards, self-retracting lifelines, horizontal systems, vertical systems, and so on), fall-protection harnesses, fall-protection anchorages, components of such apparatus, systems, equipment, and so on, with which the arrangements disclosed herein may find use, are described e.g. in the 3M DBI-SALA Fall Protection Full Line Catalog 2018.

The arrangements disclosed herein may be used at any worksite at which fall protection is used. The concept of a worksite encompasses any structure, facility, indoor area, outdoor area, and so on, at or in which any of a variety of activities (whether one-time or ongoing) may occur. Such activities may include e.g. new construction, repair, maintenance, refurbishing, inspection, deposition and/or retrieval of items, and so on. Such activities do not necessarily need to involve e.g. construction or industrial production. Rather, a worksite may take the form of any location (such as a warehouse) in which equipment is used (e.g. an aerial lift such as an order picker or the like) that causes fall protection to be appropriate. The term worksite of course encompasses environments such as towers, bridges, mine shafts, cargo holds, and so on.

Under no circumstances will the use of a composite connector arranged in the general manner disclosed herein relieve a user of the composite connector (e.g. a user of a fall-protection apparatus that includes such a connector) of the duty to follow all appropriate laws; rules; codes; standards as promulgated by applicable bodies (e.g. ANSI); instructions as provided by the manufacturer of the fall-protection apparatus, instructions as provided by the entity in charge of a worksite or other facility at which the fall-protection apparatus is used, and so on. By way of one example, some jurisdictions may require that after a user fall or similar event, a connector and/or an entire fall-protection apparatus such as an SRL should be returned to the manufacturer for inspection and possible servicing, even if no obvious damage to the connector and/or apparatus is evident. All such laws, rules, codes, standards, guidelines, procedures, etc., regarding such practices are to be followed regardless of the presence of any arrangement of the general type disclosed herein.

It will be apparent to those skilled in the art that the specific exemplary elements, structures, features, details, configurations, etc., that are disclosed herein can be modified and/or combined in numerous embodiments. Any embodiment disclosed herein may be used in combination with any other embodiment or embodiments disclosed herein. While a limited number of exemplary combinations are presented herein, many and varied combinations are envisioned and are only prohibited in the specific instance of a combination that is incompatible. All such variations and combinations are contemplated by the inventor as being within the bounds of the conceived invention, not merely those representative designs that were chosen to serve as exemplary illustrations. Thus, the scope of the present invention should not be limited to the specific illustrative structures described herein, but rather extends at least to the structures described by the language of the claims, and the equivalents of those structures. Any of the elements that are positively recited in this specification as alternatives may be explicitly included in the claims or excluded from the claims, in any combination as desired. Any of the elements or combinations of elements that are recited in this specification in open-ended language (e.g., comprise and like terms), are considered to additionally be recited in closed-ended language (e.g., consist and derivatives thereof) and in partially closed-ended language (e.g., consist essentially, and derivatives thereof). Although various theories and possible mechanisms may have been discussed herein, in no event should such discussions serve to limit the claimable subject matter. To the extent that there is any conflict or discrepancy between this specification as written and the disclosure in any document that is incorporated by reference herein but to which no priority is claimed, this specification as written will control.

What is claimed is:

1. A composite connector for use with a fall-protection apparatus, the composite connector comprising:
a frame;
and,
a shroud that is mounted on the frame and that at least partially encompasses the frame;
wherein the shroud comprises a deformable section that at least partially defines a connection area for connecting the composite connector to a support item;
wherein the composite connector comprises a fall-detection module comprising an interruptible signal-transmissive pathway that passes through at least a portion of the deformable section of the shroud, the fall-detection module further comprising a signal source configured to transmit a signal into the interruptible signal-transmissive pathway and a signal detector configured to receive a resulting signal from the interruptible signal-transmissive pathway;
and wherein the fall-detection module is configured so that if the signal source transmits a signal into the interruptible signal-transmissive pathway but the signal detector does not receive a resulting signal from the interruptible signal-transmissive pathway, the fall-detection module registers an indication of a possible fall event.

2. The composite connector of claim 1 wherein the deformable section of the shroud of the composite connector is a permanently deformable section that is configured to permanently deform upon the permanently deformable section experiencing a force resulting from the support item impinging on the permanently deformable section, that is above a predetermined threshold.

3. The composite connector of claim 2 wherein the permanently deformable section of the shroud of the composite connector comprises at least one macroscopic cavity that is positioned outward from the interruptible signal-transmissive pathway.

4. The composite connector of claim 2 wherein the permanently deformable section of the shroud of the composite connector comprises a chamber configured for the interruptible signal-transmissive pathway to reside therein, and wherein the permanently deformable section comprises an inward wall that defines an inward boundary of the chamber and comprises an outward wall that defines an outward boundary of the chamber; and, wherein the inward wall comprises at least one force-concentration structure and wherein the outward wall comprises at least one zone of weakness.

5. The composite connector of claim 1 wherein the interruptible signal-transmissive pathway comprises at least one electrically-conductive trace that extends through at least a portion of the deformable section of the shroud, wherein the signal source is configured to transmit an electrical signal into the interruptible signal-transmissive pathway and the signal detector configured to receive a resulting electrical signal from the interruptible signal-transmissive pathway.

6. The composite connector of claim 5 wherein the at least one electrically-conductive trace is provided in the form of conductive ink that is disposed on an interior surface of the shroud.

7. The composite connector of claim 5 wherein the at least one electrically-conductive trace is provided in the form of a metal trace that is disposed on a major surface of a flex circuit that resides in a chamber configured to accept the flex circuit thereinto.

8. The composite connector of claim 7 wherein the at least one electrically-conductive metal trace is in the form of a coil that serves as an inductive sensing element that serves as part of an inductive sensor module; the inductive sensor module being configured to evaluate whether a section of the support item appears to be present within the connection area of the composite connector.

9. The composite connector of claim 1 wherein the composite connector is a composite gated hook and wherein the composite connector further comprises a gate sensor that provides an indication of whether the gate of the gated hook is secured or unsecured.

10. The composite connector of claim 1 wherein the interruptible signal-transmissive pathway comprises at least one optically-transmissive pathway that extends through at least a portion of the deformable section of the shroud, wherein the signal source is configured to transmit an optical signal into the interruptible signal-transmissive pathway and the signal detector configured to receive a resulting optical signal from the interruptible signal-transmissive pathway.

11. The composite connector of claim 10 wherein the at least one optically-transmissive pathway is in the form of at least one optical fiber that extends through at least a portion of the deformable section of the shroud.

12. The composite connector of claim 1 wherein the deformable section of the shroud and the interruptible signal-transmissive pathway of the fall-detection module are configured so that deformation of the deformable section of the shroud causes a breakage in the interruptible signal-transmissive pathway that the signal detector does not receive the resulting signal from the interruptible signal-transmissive pathway.

13. The composite connector of claim 1 wherein a secondary layer is provided in the deformable section of the shroud, the secondary layer being configured so that deformation of the deformable section of the shroud causes a change in physical form of the secondary layer, which change in physical form of the secondary affects the interruptible signal-transmissive pathway so that the signal detector does not receive the resulting signal from the interruptible signal-transmissive pathway.

14. The composite connector of claim 13 wherein the signal-transmissive pathway comprises at least one electrically-conductive trace and wherein the secondary layer is an electromagnetic shielding layer.

15. The composite connector of claim 1 wherein the fall-detection module is configured so that if the signal detector continues to not receive the resulting signal from the interruptible signal-transmissive pathway for a predetermined period of time, the fall-detection module issues a notification of a possible fall event.

16. The composite connector of claim 1 wherein the fall-detection module is configured so that if the signal source transmits a signal into the interruptible signal-transmissive pathway but the signal detector does not receive the resulting signal from the interruptible signal-transmissive pathway, the fall-detection module registers a primary indication of a possible fall event; and wherein the fall-detection module is further configured with an additional sensing system that can provide a secondary indication of a possible fall event that is independent of the primary indication of the possible fall event, and wherein the fall-detection module considers both the primary indication of the possible event and the secondary indication of the possible fall event, when determining whether to issue a possible-fall notification.

17. A fall-protection apparatus configured to be used with a fall-protection harness that is wearable by a human user, the fall-protection apparatus comprising the composite connector of claim 1 attached to a distal end of a safety line of the fall-protection apparatus.

18. A fall-protection system comprising the fall-protection apparatus of claim 17 connected to the fall-protection harness, and wherein the support item is a D-ring of the fall-protection harness, with at least a portion of the D-ring passing through the connection area of the composite connector.

19. A method of detecting a possible fall event of a human user of the fall-protection system of claim 18, the method comprising the steps of:
transmitting a signal into the interruptible signal-transmissive pathway and receiving a resulting signal from the interruptible signal-transmissive pathway;
and,
if the resulting signal is not received from the signal-transmissive pathway, registering an indication of a possible fall event.

20. The fall-protection apparatus of claim 17 wherein the fall-protection apparatus is a self-retracting lifeline (SRL) and wherein the composite connector is a composite gated hook that is attached to a distal end of a safety line of the self-retracting lifeline and that is configured to define the connection area for connecting the composite connector to a support item that is a D-ring of the fall-protection harness.
